(19) United States
(12) Patent Application Publication
(10) Pub. No.: US 2026/0006907 A1
(43) Pub. Date: Jan. 1, 2026

(54) SEMICONDUCTOR DEVICES WITH INSULATION FEATURES

(71) Applicant: Taiwan Semiconductor Manufacturing Company, Ltd., Hsinchu (TW)

(72) Inventors: Tzu-Ging Lin, Kaohsiung (TW); Yun-Chen Wu, Hsinchu (TW); Bing-Hung Chen, Taipei (TW)

(73) Assignee: Taiwan Semiconductor Manufacturing Company, Ltd., Hsinchu (TW)

(21) Appl. No.: 18/759,405

(22) Filed: Jun. 28, 2024

(51) Int. Cl. H01L 27/092; H01L 21/28; H01L 21/8238; H01L 29/06; H01L 29/423; H01L 29/66; H01L 29/775; H01L 29/786

(52) U.S. Cl. CPC H10D 84/85; H01L 21/28123; H10D 30/014; H10D 30/43; H10D 30/6735; H10D 30/6757; H10D 62/121; H10D 64/017; H10D 84/0188; H10D 84/038

(57) ABSTRACT

Semiconductor devices with insulation structures and methods of fabrication are provided. A semiconductor device includes a first fin structure located over a substrate; a first gate segment located over the first fin structure; a second fin structure located over the substrate; a second gate segment located over the second fin structure; and an insulation feature located between the first fin structure and the second fin structure and located between the first gate segment and the second gate segment, wherein the insulation feature extends laterally from a first sidewall nearest the first gate segment to a second sidewall nearest the second gate segment; wherein the insulation feature includes a bottom layer and a top layer located over the bottom layer; and wherein the top layer forms an uppermost surface of the insulation feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIG. 2 illustrates a top-down view of a semiconductor device, according to some embodiments.

FIGS. 3-9 are cross-sectional Y-cut views of a device during successive stages of fabrication of the method of FIG. 1, in accordance with some embodiments.

FIGS. 10-23 are cross-sectional alternating Y-cut and X-cut views of a device during successive stages of fabrication of the method of FIG. 1, in accordance with some embodiments.

FIG. 24 is a flow chart illustrating a method, in accordance with some embodiments.

FIGS. 25-40 are cross-sectional alternating Y-cut and X-cut views of a device during successive stages of fabrication of the method of FIG. 24, in accordance with some embodiments.

FIG. 41 is a cross-sectional view of an insulation feature formed according to the method of FIG. 1 or method of FIG. 24, in accordance with some embodiments.

FIG. 42 illustrates a top-down view of a semiconductor device, according to some embodiments.

FIGS. 43-46 are cross-sectional alternating Y-cut and X-cut views of a device during successive stages of fabrication of a method for forming a semiconductor device with the structure of FIG. 42, in accordance with some embodiments.

FIG. 47 illustrates a top-down view of a semiconductor device, according to some embodiments.

FIGS. 48-51 are cross-sectional alternating Y-cut and X-cut views of a device during successive stages of fabrication of a method for forming a semiconductor device with the structure of FIG. 47, in accordance with some embodiments.

FIGS. 52-59 are cross-sectional alternating Y-cut and X-cut views of a device during successive stages of fabrication of a method, such as the method of FIG. 1, for forming a semiconductor device, in accordance with some embodiments.

FIG. 60 is a flow chart illustrating a method, in accordance with some embodiments.

FIGS. 61-78 are cross-sectional alternating Y-cut and X-cut views of a device during successive stages of fabrication of the method of FIG. 24, in accordance with some embodiments.

FIGS. 79-86 are cross-sectional alternating Y-cut and X-cut views of a device during successive stages of fabrication of the method of FIG. 24, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of an insulation structure, such as a Continuous Poly On Diffusion Edge (CPODE) structure or a Continuous Metal On Diffusion Edge (CMODE) structure, that divides a fin in two. In certain embodiments, a portion of a selected fin structure is removed and replaced with insulation material.

In embodiments herein, CMODE processing methods, i.e., formation of the insulation feature after metal gate formation, or CPODE processing methods, i.e., before metal gate formation, are provided. In certain embodiments, dielectric structures such cut-poly gate dielectric structures, cut-metal gate dielectric structures, or dummy fins form sidewalls of the cavity etched during the CMODE or CPODE process. Thus, the insulation feature is formed in contact with the dielectric structures. In other embodiments, the insulation features directly contacts remaining gate segments.

In certain embodiments, the insulation feature is formed as a bi-layer structure, with a bottom layer covered by, and encapsulated by, a top layer. In certain embodiments, the bottom layer is silicon oxide. In certain embodiments, the top layer is silicon nitride. Due to the encapsulation of the silicon oxide under the silicon nitride, later processes selective to etching silicon oxide do not damage the insulation feature. Further, in embodiments in which the insulation feature directly contact gate segments, the bottom silicon oxide layer is located below the sidewall interface with gate segments. Thus, no metal/oxide interface is formed.

Embodiments of the present disclosure offer advantages over the existing art, though it is understood that other embodiments may offer different advantages, not all advantages are necessarily discussed herein, and no particular advantage is required for all embodiments.

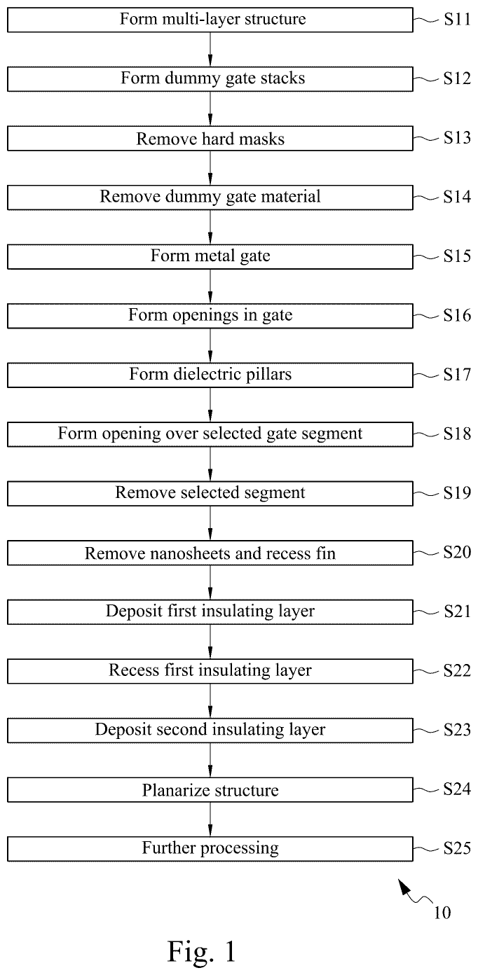

For purposes of the discussion that follows, FIG. 1 provides a flow chart for a method 10 for fabricating a semiconductor device 100 during a semiconductor fabrication process. In method 10, the dielectric structure 110 is formed as a cut-metal gate dielectric structure. Specifically, the dielectric structure 110 is formed in an opening formed by cutting a segment out of the metal gate.

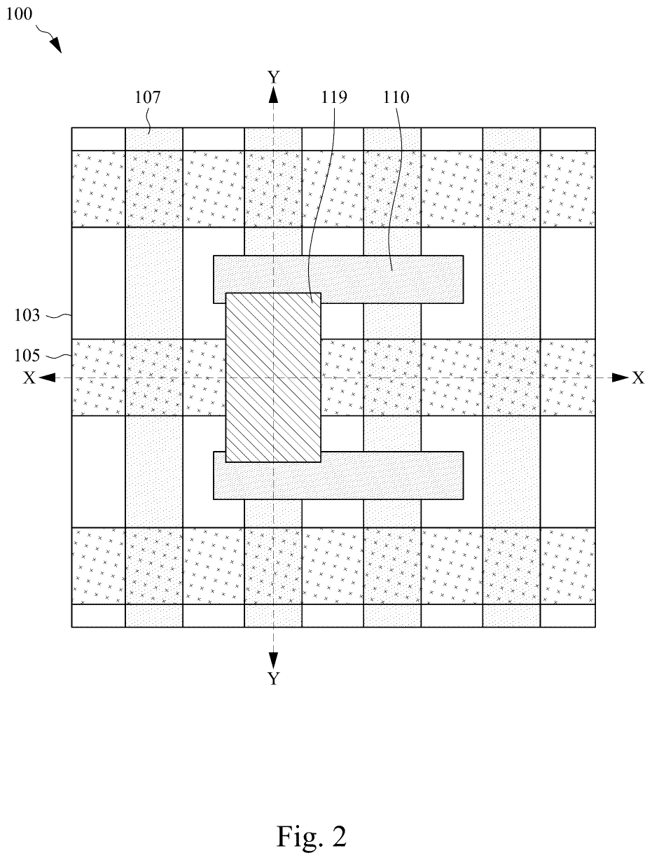

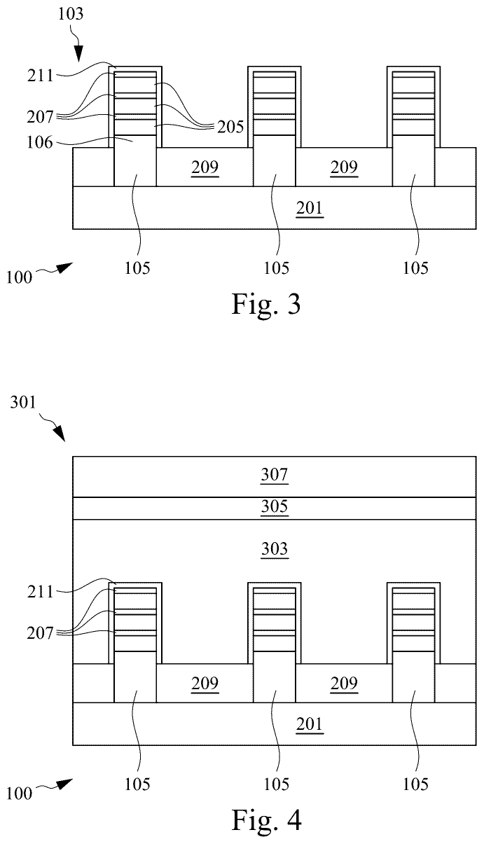

Method 10 is described below with reference to FIGS. 2-12 which illustrate the semiconductor device 100 at various stages of fabrication according to method 10. FIG. 2 illustrates a top-down view of an intermediate structure in forming a device 100, such as a gate-all-around (GAA) semiconductor device, according to some embodiments. FIGS. 3-12 are cross-sectional views in which the vertical direction is defined by the Z-axis and the lateral direction is defined by the Y-axis. It is understood that method 10 includes steps having features of a complementary metal-oxide-semiconductor (CMOS) technology process flow and thus, are only described briefly herein. Also, additional steps may be performed before, after, and/or during method 10.

In FIG. 2, the device 100 includes a multi-layer structure 103 comprising a plurality of nanosheets formed over a semiconductor substrate 201 (illustrated in the following figures), semiconductor structures 105, such as fins, formed in the multi-layer structure 103, and a plurality of gates 107 over the fins 105. FIG. 2 further illustrates a plurality of dielectric structures 110 separating two of the gates 107 and an insulation feature 119 dividing one of the fins 105 in two and intersecting the dielectric structures 110.

Although three fins 105 are illustrated in FIG. 2 and in the following figures, it is understood that depending on the desired design and number of the GAA semiconductor devices 100, any suitable number of fins 105 may be formed in the multi-layer structure 103 to form the desired GAA semiconductor devices 100. Furthermore, any suitable number of gates 107, insulation features 119, and dielectric structures 110 may be formed to form the desired GAA semiconductor devices 100.

In FIG. 2, the X-axis extends through the length of the fin 105 and passes through the insulation feature 119. Further, the Y-axis extends through the length of a gate 107 that has been separated by the two dielectric structures 110, through the two dielectric structures 110, and through the insulation feature 119 intersecting the two dielectric structures 110. The following cross-sectional views are taken along the Y-axis.

Referring now to FIGS. 1 and 3, a method 10 for fabricating a semiconductor device 100 includes, at operation S11, forming a multi-layer structure 103 over a semiconductor material, such as a substrate, and forming fins 105 in the multi-layer structure 103, in accordance with some embodiments.

In an embodiment the substrate 201 is a semiconductor substrate, which may be, for example, a silicon substrate, a silicon germanium substrate, a germanium substrate, a III-V material substrate (e.g., GaAs, GaP, GaAsP, AlInAs, AlGaAs, GaInAs, InAs, GaInP, InP, InSb, and/or GaInAsP; or a combination thereof), or a substrate formed of other semiconductor materials with, for example, high band-to-band tunneling (BTBT). The substrate 201 may be doped or un-doped. In some embodiments, the substrate 201 may be a bulk semiconductor substrate, such as a bulk silicon substrate that is a wafer, a semiconductor-on-insulator (SOI) substrate, a multi-layered or gradient substrate, or the like.

FIG. 3 illustrates a deposition process to form the multi-layer structure 103 in an intermediate stage of manufacturing the GAA semiconductor device 100, according to some embodiments. In particular, FIG. 3 further illustrates a series of depositions that are performed to form a multi-layer stack 203 of alternating materials of first layers 205 and second layers 207 over the substrate 201.

According to some embodiments, the first layers 205 may be formed using a first semiconductor material with a first lattice constant, such as SiGe, Ge, Si, GaAs, InSb, GaSb, InAlAs, InGaAs, GaSbP, GaAsSb, combinations of these, or the like. In some embodiments, a first layer 205 of the first semiconductor material (e.g., SiGe) is epitaxially grown on the substrate 201 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer CVD (ALCVD), ultrahigh vacuum CVD (UHVCVD), reduced pressure CVD (RPCVD), a combination thereof, or the like, may also be utilized. In some embodiments, the first layer 205 is formed to thicknesses of from about 3 nm and about 10 nm. However, any suitable thickness may be utilized while remaining within the scope of the embodiments.

After the first layer 205 has been formed over the substrate 201, a second layer 207 may be formed over the first layer 205. According to some embodiments, the second layers 207 may be formed using a second semiconductor material such as Si, SiGe, Ge, GaAs, InSb, GaSb, InAlAs, InGaAs, GaSbP, GaAsSb, combinations of these, or the like with a second lattice constant that is different from the first lattice constant of the first layer 205. In a particular embodiment in which the first layer 205 is silicon germanium, the second layer 207 is a material such as silicon. However, any suitable combination of materials may be utilized for the first layers 205 and the second layers 207.

In some embodiments, the second layer 207 is epitaxially grown on the first layer 205 using a deposition technique similar to that used to form the first layer 205. However, the second layer 207 may use any of the deposition techniques suitable for forming the first layer 205, as set forth above or any other suitable technique. According to some embodiments, the second layer 207 is formed to a similar thickness to that of the first layer 205. However, the second layer 207 may also be formed to a thickness that is different from the first layer 205. According to some embodiments, the second layer 207 may be formed to a thickness of from about 5 nm and about 15 nm. However, any suitable thickness may be used.

After forming the second layer 207 over the first layer 205, the deposition process is repeated to form the remaining material layers in the series of alternating materials of the first layers 205 and the second layers 207 until a desired topmost layer of the multi-layer stack 203 has been formed. According to the present embodiment, the first layers 205 may be formed to a same or similar first thickness and the second layers 207 may be formed to the same or similar second thickness. However, the first layers 205 may have different thicknesses from one another and/or the second layers 207 may have different thicknesses from one another and any combination of thicknesses may be used for the first layers 205 and the second layers 207. According to the present embodiment, the topmost layer of the multi-layer stack 203 is formed as a second layer 207; however, in other embodiments, the topmost layer of the multi-layer stack 203 may be formed as a first layer 205. Additionally, although embodiments are disclosed herein comprising three of the first layers 205 and three of the second layers 207, the multi-layer stack 203 may have any suitable number of layers (e.g., nanosheets). For example, the multi-layer stack 203 may comprise from two to ten nanosheets. In some embodiments, the multi-layer stack 203 may comprise equal numbers of the first layers 205 to the second layers 207; however, in other embodiments, the number of the first layers 205 may be different from the number of the second layers 207. According to some embodiments, the multi-layer stack 203 may be formed to a height of from about 12 nm to about 100 nm. However, any suitable height may be used.

FIG. 3 further illustrates, a patterning process of the multi-layer structure 103 and a formation of isolation regions 209 in an intermediate stage of manufacturing the GAA semiconductor device 100, in accordance with some embodiments. The patterning process is used to form fins 105 in the multi-layer structure 103 and to form trenches between the fins 105 in preparation for forming the isolation regions 209. The patterning process for forming the fins 105, according to some embodiments, comprises applying a photoresist over the multi-layer stack 203 and then patterning and developing the photoresist to form a mask over the multi-layer stack 203. After being formed, the mask is then used during an etching process, such as an anisotropic etching process to transfer the pattern of the mask into the underlying layers to form the trenches through the multi-layer stack 203 and into the substrate 201 to define the fins 105, wherein the fins 105 are separated by the trenches.

Additionally, while a single mask process has been described, this is intended to be illustrative and is not intended to be limiting, as the gate all around (GAA) device structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In an embodiment, the isolation regions 209 are formed as shallow trench isolation regions by depositing a dielectric material in the trenches. According to some embodiments, the dielectric material used to form the isolation regions 209 may be a material such as an oxide material (e.g., a flowable oxide), high-density plasma (HDP) oxide, or the like. The dielectric material may be formed, after an optional cleaning and lining of the trenches, using either a chemical vapor deposition (CVD) method (e.g., the HARP process), a high density plasma CVD method, or other suitable method of formation to fill or overfill the regions around the fins 105. In some embodiments, a post placement anneal process (e.g., oxide densification) is performed to densify the material of the isolation regions 209 and to reduce its wet etch rate. A chemical mechanical polishing (CMP), an etch, a combination of these, or the like may be performed to remove any excess material of the isolation regions 209.

After the dielectric material has been deposited to fill or overfill the regions around the fins 105, the dielectric material may then be recessed away from the surface of the fins 105 to form the isolation regions 209. The recessing may be performed to expose at least a portion of the sidewalls of the fins 105 adjacent to the top surface of the fins 105. The dielectric material may be recessed using a wet etch by dipping the top surface of the fins 105 into an etchant selective to the material of the dielectric material, although other methods, such as a reactive ion etch, a dry etch, chemical oxide removal, or dry chemical clean may be used.

As shown in FIG. 3, the fins 105 include a base portion 106 formed from etching the substrate, with layers 205 and 207 located over the base portion 106.

FIG. 3 further illustrates the formation of a dummy gate dielectric 211 over the exposed portions of the fins 105. After the isolation regions 209 have been formed, the dummy gate dielectric 211 may be formed by thermal oxidation, chemical vapor deposition, sputtering, or any other methods known and used in the art for forming a gate dielectric. Depending on the technique of gate dielectric formation, the dummy gate dielectric 211 thickness on the top may be different from the dummy dielectric thickness on the sidewall. In some embodiments, the dummy gate dielectric 211 may be formed by depositing a material such as silicon and then oxidizing or nitridizing the silicon layer in order to form a dielectric such as the silicon dioxide or silicon oxynitride. In such embodiments, the dummy gate dielectric 211 may be formed to a thickness of from about 3 Å to about 100 Å, such as about 10 Å. In other embodiments, the dummy gate dielectric 211 may also be formed from a high permittivity (high-k) material such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of from about 0.5 Å to about 100 Å, such as about 10 Å or less. Additionally, any combination of silicon dioxide, silicon oxynitride, and/or high-k materials may also be used for the dummy gate dielectric 211.

Cross-referencing FIGS. 1 and 4, method 10 may continue, at operation S12, forming sacrificial or dummy gate stacks 301 over the fins 105, in accordance with some embodiments. According to some embodiments, the dummy gate stacks 301 comprise a dummy gate dielectric 211, a dummy gate 303 over the dummy gate dielectric 211, a first hard mask 305 over the dummy gate 303, and a second hard mask 307 over the first hard mask 305.

In some embodiments, the dummy gate 303 comprises a conductive material and may be selected from a group comprising of polysilicon, W, Al, Cu, AlCu, W, Ti, TiAlN, TaC, TaCN, TaSiN, Mn, Zr, TiN, Ta, TaN, Co, Ni, combinations of these, or the like. The dummy gate 303 may be deposited by chemical vapor deposition (CVD), sputter deposition, or other techniques known and used in the art for depositing conductive materials. The thickness of the dummy gate 303 may be from about 5 Å to about 500 Å. The top surface of the dummy gate 303 may have a non-planar top surface, and may be planarized prior to patterning of the dummy gate 303 or gate etch. Ions may or may not be introduced into the dummy gate 303 at this point. Ions may be introduced, for example, by ion implantation techniques.

After the dummy gate 303 has been formed, the dummy gate dielectric 211 and the dummy gate 303 may be patterned. In an embodiment the patterning may be performed by initially forming a first hard mask 305 over the dummy gate 303 and forming the second hard mask 307 over the first hard mask 305.

According to some embodiments, the first hard mask 305 comprises a dielectric material such as silicon nitride (SiN), oxide (OX), silicon oxide (SiO), titanium nitride (TiN), silicon oxynitride (SiON), combinations of these, or the like. The first hard mask 305 may be formed using a process such as chemical vapor deposition, plasma enhanced chemical vapor deposition, atomic layer deposition, or the like. However, any other suitable material and method of formation may be utilized. The first hard mask 305 may be formed to a thickness of from about 20 Å to about 3000 Å, such as about 20 Å.

The second hard mask 307 comprises a separate dielectric material from the material of the first hard mask 305. The second hard mask 307 may comprise any of the materials and use any of the processes suitable for forming the first hard mask 305 and may be formed to a same or similar thickness as the first hard mask 305. In embodiments where the first hard mask 305 comprises silicon nitride (SiN), the second hard mask 307 may be e.g., an oxide (OX). However, any suitable dielectric materials, processes and thicknesses may be used to form the second hard mask.

After the first hard mask 305 and the second hard mask 307 have been formed, the first hard mask 305 and the second hard mask 307 may be patterned. Patterning of the first hard mask 305 and second hard mask 307 occurs in the X-dimension, i.e., distanced into or out of the drawing sheet for the cross-sectional views of FIGS. 3-12. Thereafter, various processes may be performed to form desired structures, etching of the dummy gate material to form distinct dummy gate stacks, formation of spacers, etching of openings for source/drain regions, epitaxial growth of source/drain regions, implant processes, and other typical gate processing. As used herein, “source/drain region(s)” or “source/drain feature(s)” may refer to a source or a drain, individually or collectively dependent upon the context.

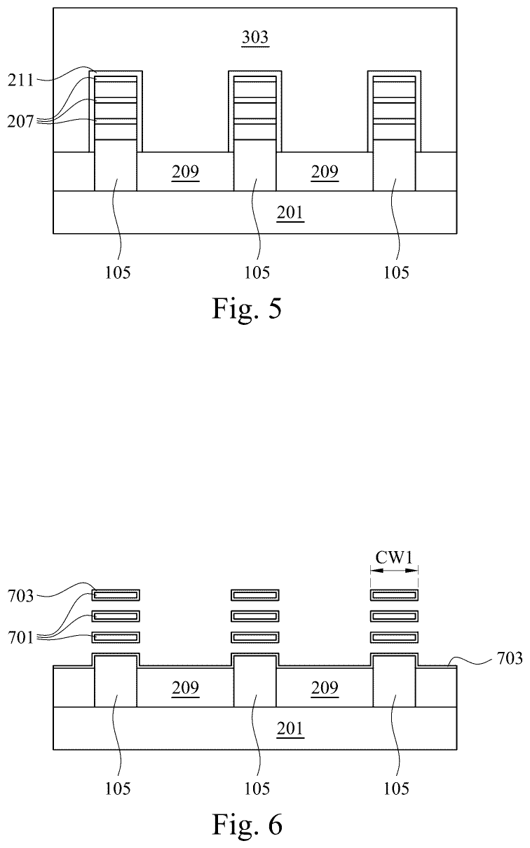

Cross-referencing FIGS. 1 and 5, method 10 may continue, at operation S13, with removal of the first hard mask 305 and the second hard mask 307. According to some embodiments, one or more etching processes and/or the chemical mechanical planarization (CMP) may be utilized to remove the first hard mask 305 and the second hard mask 307. As such, the dummy gate 303 is exposed after the removal of the first hard mask 305.

Cross-referencing FIGS. 1 and 6, method 10 may continue, at operation S14, with removing the dummy gate 303 and the dummy gate dielectric 211. FIG. 6 further illustrates a wire-release process to form nanostructures 701, i.e., vertically-spaced nanosheets, from the second layers 207, in accordance with some embodiments. FIG. 6 further illustrate the formation of a gate dielectric 703 over the nanostructures 701, according to some embodiments.

After being exposed by removal of the first hard mask 305, the dummy gate 303 may be removed in order to expose the underlying dummy gate dielectric 211. In an embodiment the dummy gate 303 is removed using, e.g., one or more wet or dry etching process that utilizes etchants that are selective to the material of the dummy gate 303. However, any suitable removal process may be utilized.

After the dummy gate dielectric 211 has been exposed by removal of the dummy gate 303, the dummy gate dielectric 211 may be removed. In an embodiment the dummy gate dielectric 211 may be removed using, e.g., a wet etching process, although any suitable etching process may be utilized.

After the dummy gate dielectric 211 has been removed (which also exposes the sides of the first layers 205), the first layers 205 may be removed from between the substrate 201 and from between the second layers 207 in a wire release process step. The wire release process step may also be referred to as a sheet release process step, a sheet formation process step, a nanosheet formation process step or a wire formation process step. In an embodiment the first layers 205 may be removed using a wet etching process that selectively removes the material of the first layers 205 (e.g., silicon germanium (SiGe)) without significantly removing the material of the substrate 201 and the material of the second layers 207 (e.g., silicon (Si)). However, any suitable removal process may be utilized.

For example, in an embodiment, an etchant such as a high temperature HCl may be used to selectively remove the material of the first layers 205 (e.g., SiGe) without substantively removing the material of the substrate 201 and/or the material of the second layers 207 (e.g., Si). Additionally, the wet etching process may be performed at a temperature of from 400° C. to about 600° C., such as about 560° C., and for a time of from about 100 seconds to about 600 seconds, such as about 300 seconds. However, any suitable etchant, process parameters, and time can be utilized.

By removing the material of the first layers 205, the sides of the second layers 207 (relabeled nanostructures 701 in FIG. 6) are exposed. According to some embodiments, the nanostructures 701 are vertically separated or spaced from one another by a spacing of from about 5 nm to about 15 nm, such as about 10 nm. The nanostructures 701 comprise the channel regions between opposite ones of the source/drain regions and have a channel length (in the X-direction into and out of the drawing sheet) of from about 5 nm to about 180 nm, such as about 10 nm, and a channel width, in the Y-direction, of from about 8 nm to about 100 nm, such as about 30 nm. In an embodiment the nanostructures 701 are formed to have the same thicknesses as the original thicknesses of the second layers 207 such as from about 3 nm to about 15 nm, such as about 8 nm, although the etching processes may also be utilized to reduce the thicknesses.

In some embodiments, the sheet release step may include an optional step for the partial removal of the material of the second layers 207 (e.g., by over etching) during removal of the first layers 205. As such, the thicknesses of the nanostructures 701 are formed to have reduced thicknesses as compared to the original thickness of the second layers 207. As such, the nanostructures 701 may have thicknesses that are less than the thicknesses of the original second layers 207.

Although FIG. 6 illustrates the formation of three of the nanostructures 701, any suitable number of the nanostructures 701 may be formed from the nanosheets provided in the multi-layer stack 203. For example, the multi-layer stack 203 may be formed to include any suitable number of the first layers 205 and any suitable number of the second layers 207. As such, a multi-layer stack 203 comprising fewer first layers 205 and fewer second layers 207, after removal of the first layers 205, forms one or two of the nanostructures 701. Whereas, a multi-layer stack 203 comprising many of the first layers 205 and many of the second layers 207, after removal of the first layers 205, forms four or more of the nanostructures 701.

FIG. 6 further illustrates the formation of the gate dielectric 703 over the nanostructures 701, according to some embodiments. In an embodiment the gate dielectric 703 comprises a high-k material (e.g., K greater than or equal to 9) such as Ta₂O₅, Al₂O₃, Hf oxides, Ta oxides, Ti oxides, Zr oxides, Al oxides, La oxides (e.g., HfO₂, HfSiO, HfSiON, HfTaO, HfTiO, HfZrO, LaO, ZrO, TiO), combinations of these, or the like, deposited through a process such as atomic layer deposition, chemical vapor deposition, or the like. In some embodiments, the gate dielectric 703 comprises a nitrogen doped oxide dielectric that is initially formed prior to forming a metal content high-K (e.g., K value>13) dielectric material. The gate dielectric 703 may be deposited to a thickness of from about 1 nm to about 3 nm, although any suitable material and thickness may be utilized. In certain embodiments, the gate dielectric 703 wraps around the nanostructures 701, thus forming channel regions between the source/drain regions. In some embodiments, a silicon-based interfacial layer may be formed around the nanostructures before deposition of the high-K gate dielectric 703. In certain embodiments, the thickness of the interfacial layer is from 0.5 nm to 2 nm.

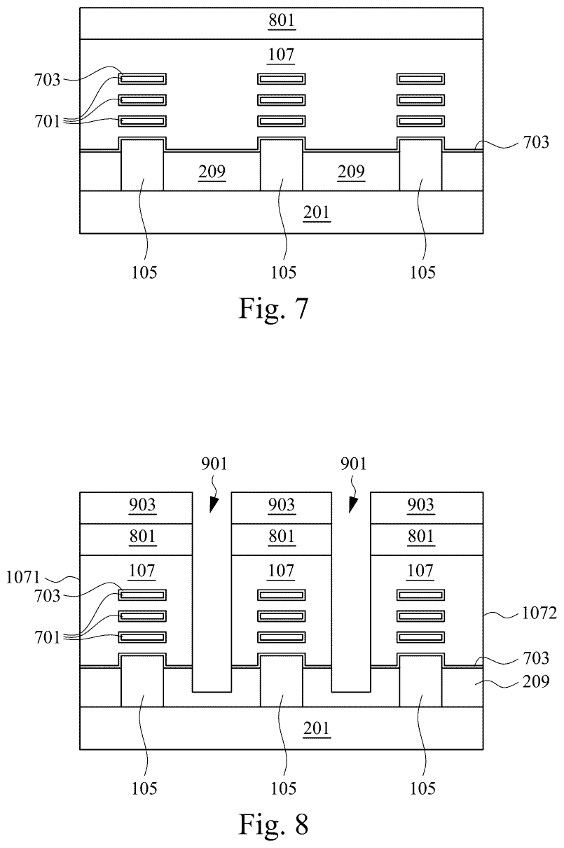

Cross-referencing FIGS. 1 and 7, method 10 may continue, at operation S15, with forming a metal gate over the fin structures. For example, method 10 includes forming metal gates 107. Optionally, gate caps 801 may be formed over the metal gates, in accordance with some embodiments. After the gate dielectric 703 has been formed, the metal gates are formed to surround the nanostructures 701. For example, inter-sheet portions of the metal gate are located between the nanosheets 701.

In some embodiments, the metal gates are formed using multiple layers, each layer deposited sequentially adjacent to each other using a highly conformal deposition process such as atomic layer deposition, although any suitable deposition process may be utilized. According to some embodiments, the metal gates may comprise a capping layer, a barrier layer, an n-metal work function layer, a p-metal work function layer, and a fill material.

The capping layer may be formed adjacent to the gate dielectric 703 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings left behind by the removal of the dummy gate 303 have been filled, the materials of the gate electrode 107 and the gate dielectric 703 may be planarized in order to remove any material that is outside of the openings left behind by the removal of the dummy gate 303. In a particular embodiment the removal may be performed using a planarization process such as chemical mechanical polishing, although any suitable planarization and removal process may be utilized. According to some embodiments, the gate electrodes may be formed to a length of from about 8 nm to about 30 nm. However, any suitable length may be used.

After being formed, the metal gates may be recessed. According to some embodiments, the metal gates may be recessed using an etching process such as a wet etch, a dry etch, combinations, or the like.

The optional gate caps 801 may be formed by initially depositing a dielectric material over the metal gates to fill and/or overfill the recesses. In some embodiments, the gate caps 801 are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps 801 are formed using a metal oxide of materials such as zirconium (Zr), hafnium (Hf), aluminum (Al), or the like. Furthermore, the gate caps 801 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps 801 may be planarized using a planarization process such as a chemical mechanical polishing process.

Cross-referencing FIGS. 1 and 8, method 10 may continue, at operation S16, with forming openings 901 in a cut-metal gate process, in accordance with some embodiments. After the gate caps 801 have been planarized, a masking layer 903 may be deposited over the planar surfaces of the gate caps 801. After being deposited, the masking layer 903 is patterned to expose the underlying materials including the gate caps 801 in desired locations of the cut-metal gate dielectric structures 110 that are to be formed.

After being patterned, the masking layer 903 is used as an etching mask to etch the underlying materials to form the openings 901 (e.g., trenches, recesses, channels or the like). In the etching process, the materials of the gate caps 801 and the metal gates are etched using an anisotropic etching process. In certain embodiments, the etch process continues through the gate dielectric 703 and into the isolation regions 209. The openings 901 may be formed between adjacent fins 105 and may be formed to cut through one or more metal gates. According to some embodiments, two of the openings 901 are formed to cut through two adjacent metal gates and are located on opposite sides of one or more of the fins 105, e.g., selected fin(s), as shown in FIG. 2. After the openings 901 have been formed, the masking layer 903 is removed.

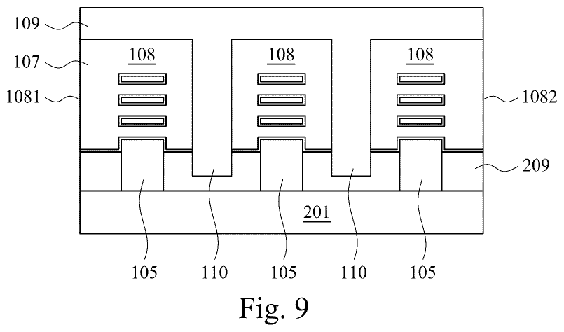

Cross-referencing FIGS. 1 and 9, method 10 may continue, at operation S17, with forming dielectric pillars 110 from dielectric material 109, in accordance with some embodiments. In the embodiment of FIG. 9, the dielectric pillars 110 are cut-metal gate dielectric structures 110.

After the openings 901 have been formed, masking layer 903 may be removed. Then, the dielectric pillars 110 are formed by initially depositing a dielectric material 109 to fill and overfill the openings 901. In accordance with some embodiments, the dielectric material 109 is formed using any dielectric material and deposition process suitable for forming the gate caps 801. In some embodiments, the dielectric material 109 is the same as the dielectric material used to form the gate caps 801, although the dielectric materials may be different. In the embodiment of FIG. 9, the optional gate caps 801 are not present, or may be considered to be part of the dielectric material 109. For example, in embodiments where the gate caps 801 are formed using silicon nitride (SiN), dielectric material 109 may also be silicon nitride (SiN) formed in a deposition process such as Atomic Layer Deposition (ALD). However, any suitable dielectric materials and deposition processes may be used. According to some embodiments, the dielectric pillars 110 are formed with a width between adjacent metal gate segments 108 of from about 5 nm to about 50 nm, such as about 10 nm. However, any suitable widths may be used.

As shown, the dielectric pillars 110 extend into the STI regions 209 and divide the metal gates, which are relatively long, into a plurality of segmented gate electrodes 108 which are relatively short. The dielectric pillars 110 may be used to isolate the gate segments 108 from one another. Furthermore, the excess dielectric material 109 of the dielectric pillars 110 outside of the openings 901 may be retained and used as a masking layer in the Continuous Metal On Diffusion Edge (CMODE) process.

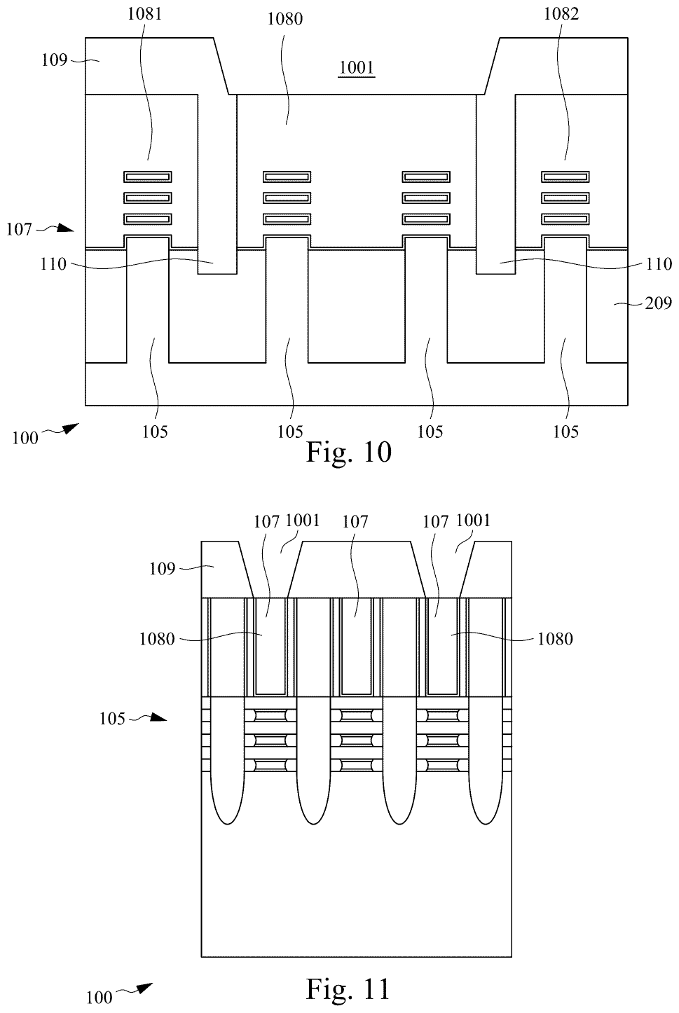

Cross-referencing FIG. 1 and FIGS. 10 and 11, method 10 may continue, at operation S18, with forming an opening 1001 in the dielectric material 109 over each segment 1080 of metal gate 107 to be removed in an initial step of forming a Continuous Metal On Diffusion Edge (CMODE) structure, in accordance with some embodiments. The CMODE structure may also be referred to herein as an isolation structure or a cut-MODE structure and is discussed in greater detail with the following figures. FIG. 10 is a Y-cut cross-sectional view taken along a gate 107 and across four fins 105 and FIG. 11 is an X-cut cross-sectional view taken along a fin 105 and across three metal gates 107.

In certain embodiments, forming the opening 1001 in the dielectric material 109 may include depositing a variety of masking layers, such as including a carbon based bottom layer, an oxide based middle layer, and an extreme ultraviolet (EUV) photo resist top layer. The process may include performing an extreme ultraviolet lithography (EUV) photo resist exposure technique to pattern the photo resist, followed by etching of the middle layer and bottom layer. Then, the dielectric material 109 is etched to form the opening 1001. The dielectric material 109 may be etched by a dry etch process, such as a process suitable for etching a silicon nitride material.

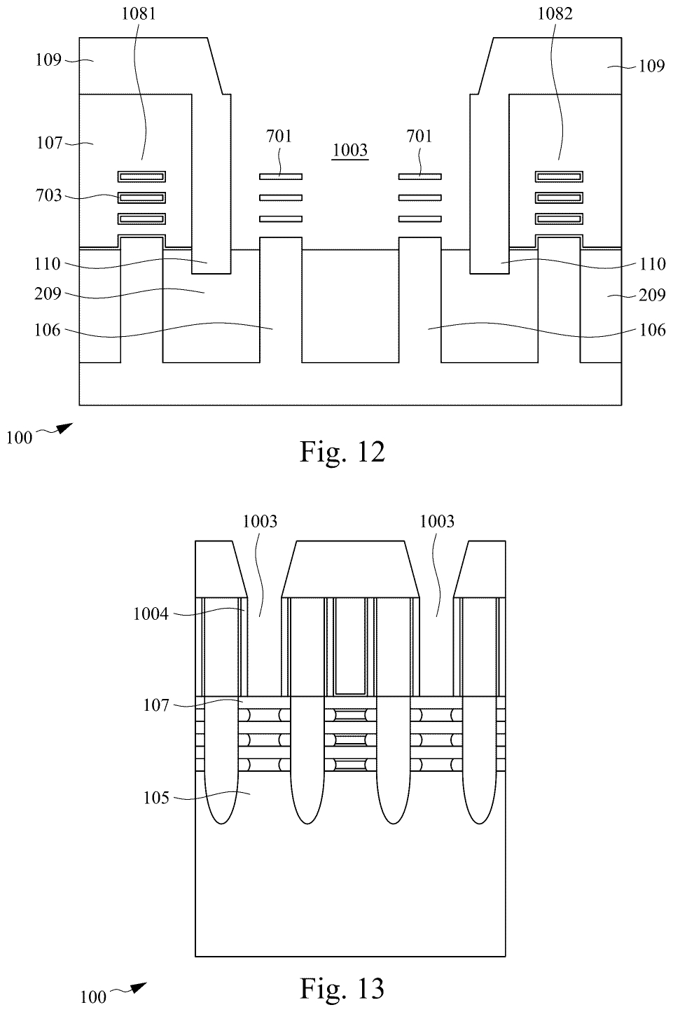

Cross-referencing FIG. 1 and FIGS. 12 and 13, method 10 may continue, at operation S19, with removing the metal gate segment 1080. FIG. 12 is a Y-cut cross-sectional view taken along a gate 107, similar to FIG. 10, and FIG. 13 is an X-cut cross-sectional view taken along a fin 105, similar to FIG. 11.

In certain embodiments, removing the metal gate segment 1080 forms an opening 1003 and includes selectively removing the metal gate segment 1080, including the metal gate material 107 and high k gate dielectric 703. The metal gate segment 1080 may be removed by a dry or wet etch. In certain embodiments, the process may remove all of the metal gate segment 1080 between the dielectric pillars 110 and over the STI regions 209, as shown in FIG. 12. Further, the process may remove all of the metal gate segment 1080 between the sidewall spacers 1004 and over the mesa or base portion 106 of fins 105, including between nanosheets 701.

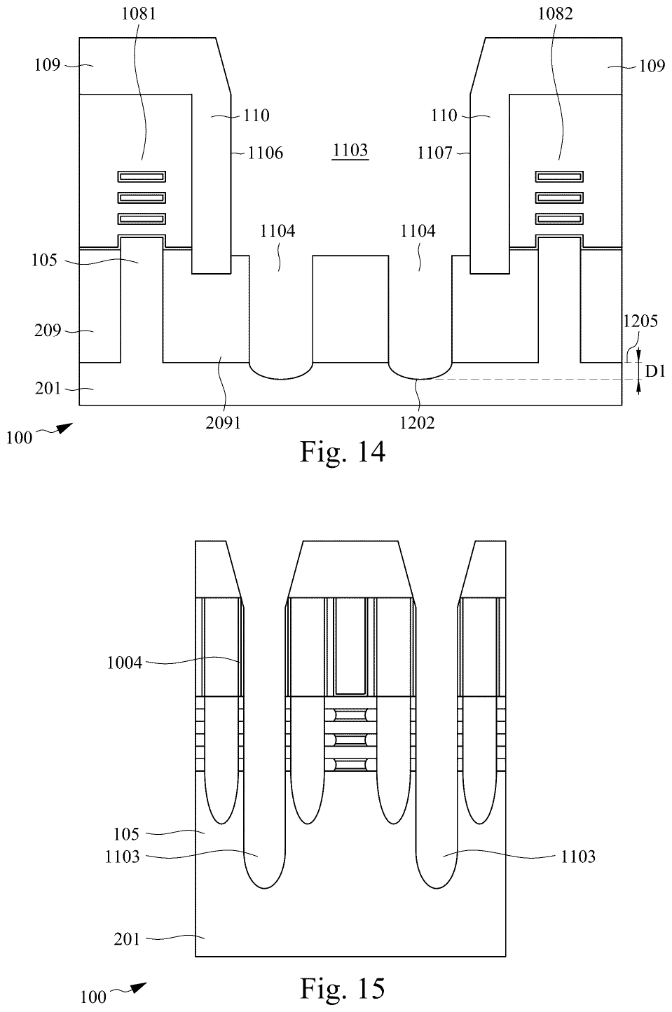

Cross-referencing FIG. 1 and FIGS. 14 and 15, method 10 may continue, at operation S20, with removing the nanostructures 701 and recessing the selected fins 105 to form cavity or opening 1103. FIG. 14 is a Y-cut cross-sectional view taken along a gate 107, similar to FIG. 10, and FIG. 15 is an X-cut cross-sectional view taken along a fin 105, similar to FIG. 11.

After uncovering the nanostructures 701 and a portion of the fins 105 protruding above the isolation regions 209, a further etching process may be used to remove the materials of the nanostructures 701 and to recess the fins 105. In certain embodiments, the uncovered fins 105 are removed, and a portion of the underlying substrate 201 is etched. As a result, an upper surface of the substrate 201 is recessed to a recessed surface 1202 at a depth D1 from the upper surface 1205 of the substrate 201 or bottom surface 2091 of STI region 209. Depth D1 may be from 0 to 100 nanometers (nm). In applications where low leakage current is desired, depth D1 may be deep, such as at least 50 nm, at least 60 nm, at least 70 nm, at least 80 nm, or at least 90 nm. In applications sensitive to parasitic currents in the well resulting from alteration of well electrostatics due to a deep depth D1, depth D1 may be shallow, such as at most 50 nm, at most 40 nm, at most 30 nm, at most 20 nm, or at most 10 nm. As shown, the opening 1103 includes projections or fin cavities 1104 that extend through the STI region 209 to the recessed surface 1202. The opening 1103 has sidewalls 1106 and 1107 defined by the dielectric structures 110.

In certain embodiments, the etch process is a plasma etch.

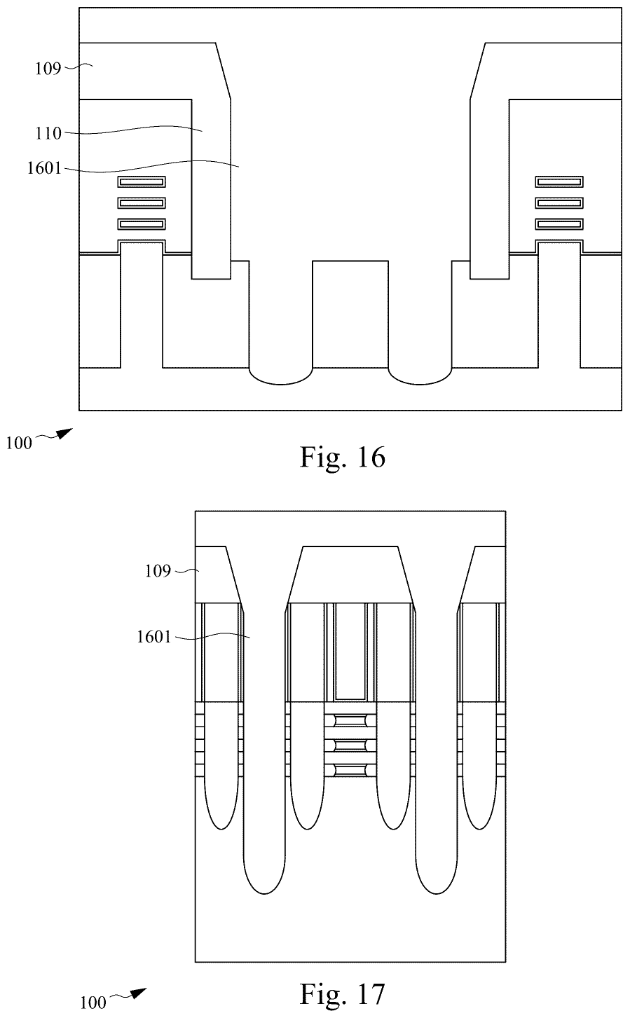

Cross-referencing FIG. 1 and FIGS. 16 and 17, method 10 may continue, at operation S21, with forming a first insulating dielectric material 1601 in the opening 1103. FIG. 16 is a Y-cut cross-sectional view taken along a gate 107, similar to FIG. 10, and FIG. 17 is an X-cut cross-sectional view taken along a fin 105, similar to FIG. 11.

As shown in FIGS. 16 and 17, the first insulating dielectric material 1601 may completely fill the openings 1103.

In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is low-k silicon oxide.

In certain embodiments, the first insulating dielectric material 1601 may be deposited with a refill process. In one example, the dielectric structure 1601 may be deposited by chemical vapor deposition (CVD), atomic layer deposition (ALD), spin-on coating, or other suitable techniques. As shown, the first insulating dielectric material 1601 may be first formed as a blanket layer covering the surface of the dielectric material 109.

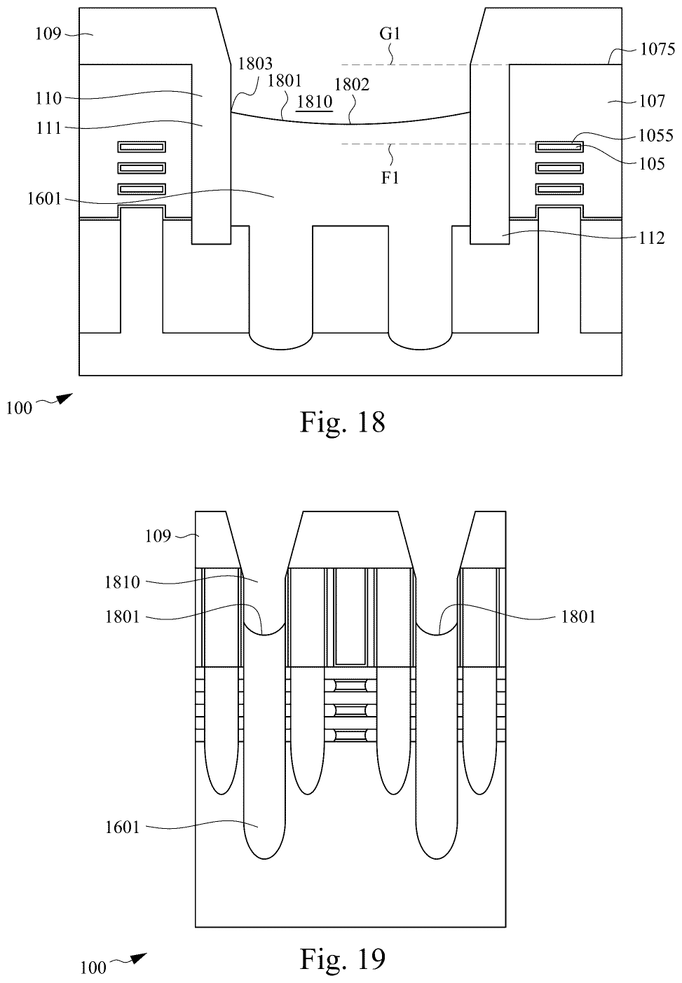

Cross-referencing FIG. 1 and FIGS. 18 and 19, method 10 may continue, at operation S22, with recessing the first insulating dielectric material 1601 to form a recess or opening 1810. FIG. 18 is a Y-cut cross-sectional view taken along a gate 107, similar to FIG. 10, and FIG. 19 is an X-cut cross-sectional view taken along a fin 105, similar to FIG. 11.

As shown in FIGS. 18 and 19, the first insulating dielectric material 1601 is recessed to a recessed surface 1801. The recessed surface 1801 extends laterally between dielectric pillars 110. Specifically, the recessed surface 1801 contacts a first dielectric pillar 111 and an adjacent second dielectric pillar 112.

As shown, the metal gate 107 has an uppermost surface 1075 that defines an upper gate plane G1.

In certain embodiments, the recessed surface 1801 has a lowest point 1802 at a height below the upper gate plane G1. In certain embodiments, the recessed surface 1801 contacts the first dielectric pillar 111 at a height below the upper gate plane G1. In certain embodiments, the recessed surface 1801 contacts the second dielectric pillar 112 at a height below the upper gate plane G1. In certain embodiments, the recessed surface 1801 has an uppermost point 1803, such as at the interface with the first dielectric pillar 111 or with the second dielectric pillar 112, at a height below the upper gate plane G1. In certain embodiments, the entirety of the recessed surface 1801 is at a height below the upper gate plane G1. As used herein, a point at a height below the upper gate plane G1 is located between the upper gate plane G1 and the substrate 201.

As shown, each fin 105 has an uppermost surface 1055 that defines an upper gate plane F1.

In certain embodiments, the lowest point 1802 of the recessed surface 1801 is at a height above the upper fin plane F1. In certain embodiments, the recessed surface 1801 contacts the first dielectric pillar 111 at a height above the upper fin plane F1. In certain embodiments, the recessed surface 1801 contacts the second dielectric pillar 112 at a height above the upper fin plane F1. In certain embodiments, the recessed surface 1801 has an uppermost point 1803, such as at the interface with the first dielectric pillar 111 or with the second dielectric pillar 112, at a height above the upper fin plane F1. In certain embodiments, the entirety of the recessed surface 1801 is at a height above the upper fin plane F1. As used herein, a point at a height above the fin plane F1 is located such that the fin plane F1 is between point and the substrate 201.

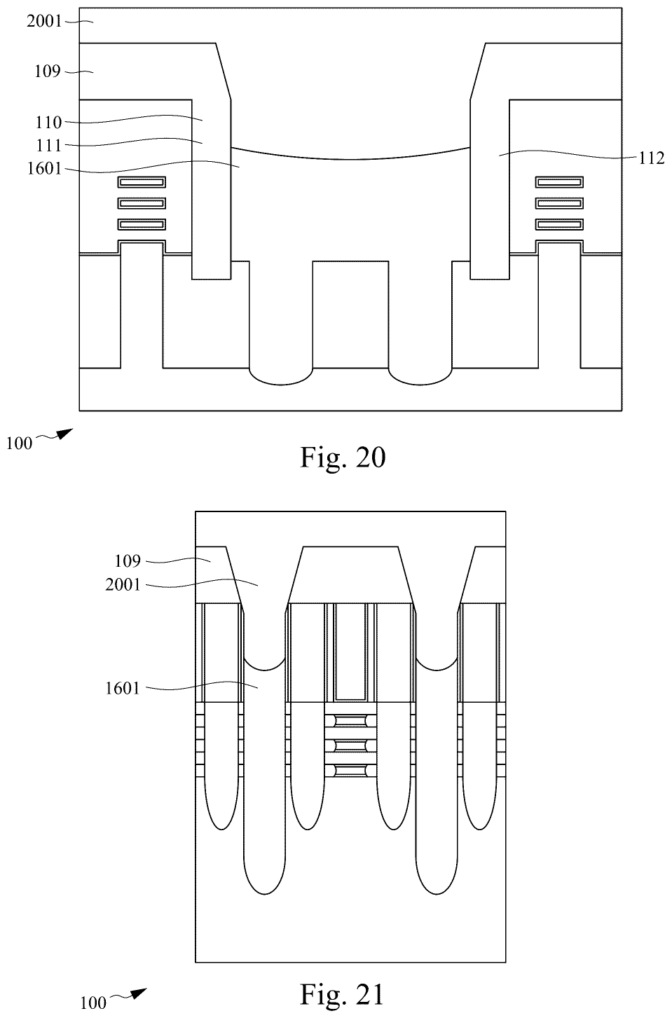

Cross-referencing FIG. 1 and FIGS. 20 and 21, method 10 may continue, at operation S23, with depositing a second insulating dielectric material 2001 in the opening 1810 over the first insulating dielectric material 1601. FIG. 20 is a Y-cut cross-sectional view taken along a gate 107, similar to FIG. 10, and FIG. 21 is an X-cut cross-sectional view taken along a fin 105, similar to FIG. 11.

As shown in FIGS. 20 and 21, the second insulating dielectric material 2001 may completely fill the openings 1810.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

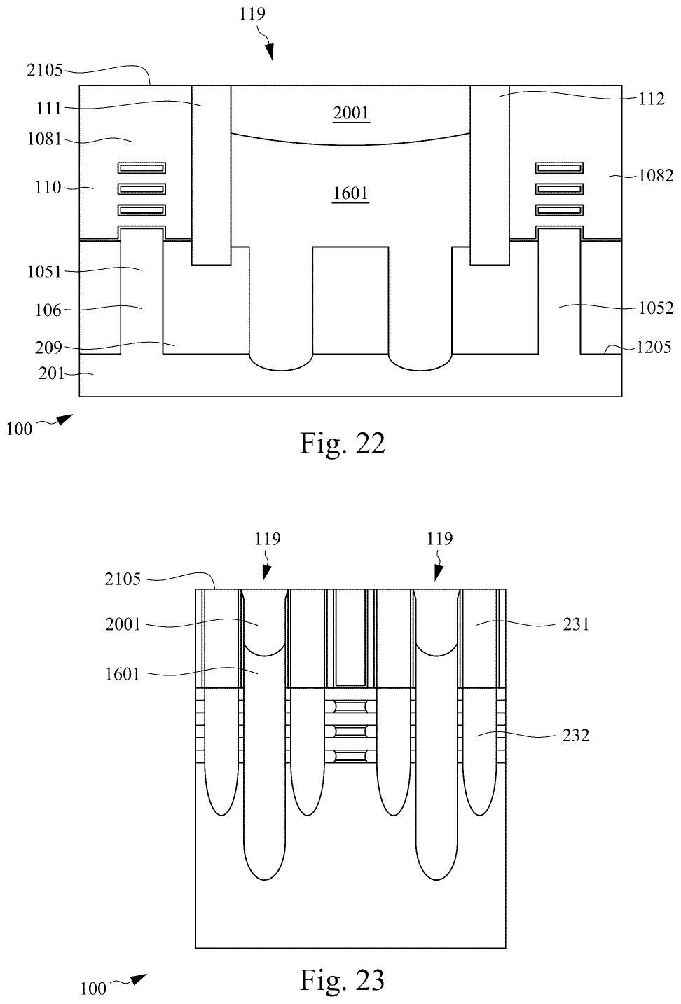

Cross-referencing FIG. 1 and FIGS. 22 and 23, method 10 may continue, at operation S24, with planarizing the structure of device 100. FIG. 22 is a Y-cut cross-sectional view taken along a gate 107, similar to FIG. 10, and FIG. 23 is an X-cut cross-sectional view taken along a fin 105, similar to FIG. 11.

As shown in FIGS. 22 and 23, the planarization process may remove all of the overburden portion of the dielectric material 109 and all of the overburden portion of the second insulating dielectric material 2001 and form the structure of device 100 with an upper surface 2101 formed by the first metal gate segment 1081, dielectric pillar 111, second insulating dielectric material 2001, dielectric pillar 112 and second metal gate segment 1082.

Operation S24 may be considered to complete the CMODE process by forming the insulation feature 119 in the form of a CMODE structure, include bottom layer or first insulating dielectric material 1601 and top layer or second insulating dielectric material 2001. As shown, each of the first insulating dielectric material 1601 and top layer or second insulating dielectric material 2001 contacts the first dielectric pillar 111 and the second dielectric pillar 112 such that the first insulating dielectric material 1601 is completely covered by, and encapsulated by, the second insulating dielectric material 2001.

As shown in FIG. 1, method 10 may continue, at operation S25, with further processing for completing the device 100. For example, the further processing may include forming interlayer dielectric and metallization layers, forming source/drain contacts to the source/drain regions, and forming source/drain vias and gate vias, in accordance with some embodiments.

Method 10 is a process for forming a CMODE insulation feature 119, i.e., the metal gate 107 is formed before a segment of the metal gate 107 is removed and replaced with the insulation feature 119. In other words, the process to form the insulation feature 119 occurs after the replacement metal gate process is performed to form the metal gate. In other embodiments, the process to form the insulation feature 119 occurs before the replacement metal gate process is performed.

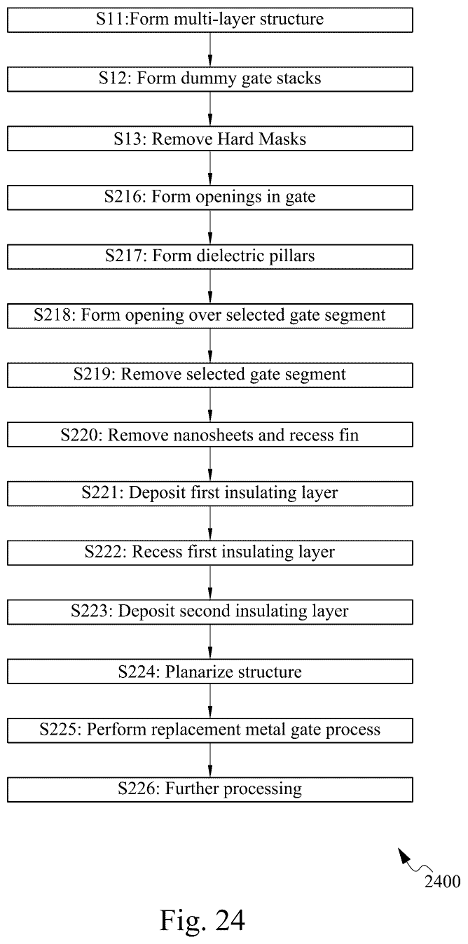

For example, referring to FIG. 24, a method 2400 for forming an insulation feature as a CPODE insulation feature 119 is illustrated. In method 2400, the dielectric structure 110 is formed as a cut-dummy gate dielectric structure, i.e., a cut-poly gate dielectric structure. Specifically, the dielectric structure 110 is formed in an opening formed by cutting a segment out of the dummy gate before formation of the replacement metal gate.

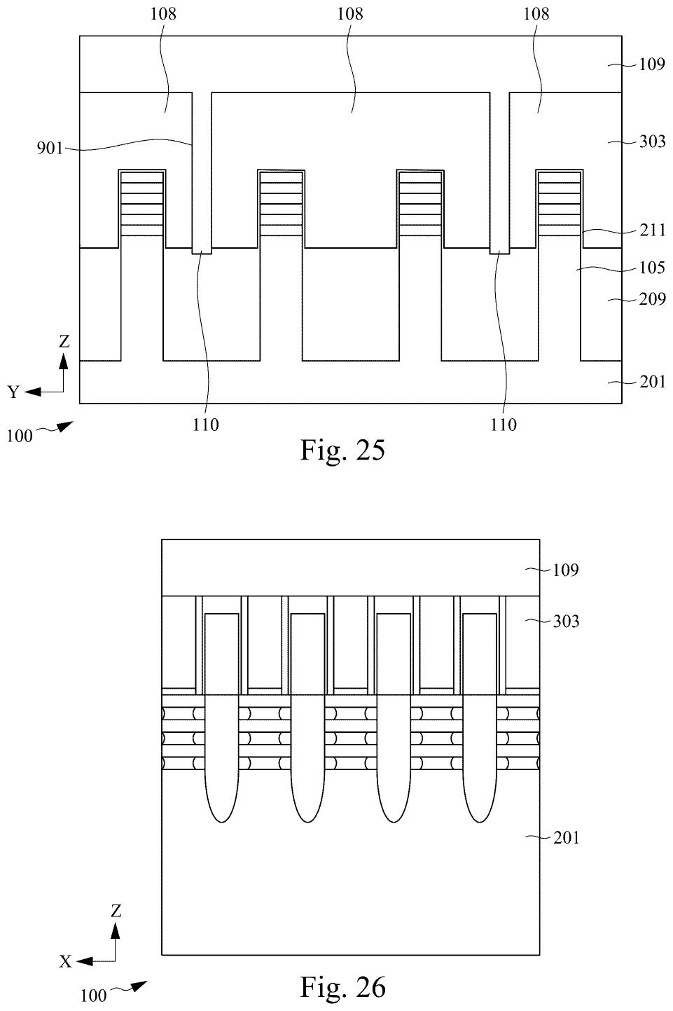

Method 2400 is described below with reference to FIGS. 2 and 25-40 which illustrate the semiconductor device 100 at various stages of fabrication according to method 2400. FIG. 2 illustrates a top-down view of an intermediate structure in forming a device 100, such as a gate-all-around (GAA) semiconductor device, according to some embodiments. FIGS. 25, 27, 29, 31, 33, 35, 37, and 39 are cross-sectional views in which the vertical direction is defined by the Z-axis and the lateral direction is defined by the Y-axis. FIGS. 26, 28, 30, 32, 34, 36, 38, and 40 are cross-sectional views in which the vertical direction is defined by the Z-axis and the lateral direction is defined by the X-axis and each view illustrates the same stage of fabrication as the immediately preceding figure.

It is understood that method 2400 includes steps having features of a complementary metal-oxide-semiconductor (CMOS) technology process flow and thus, are only described briefly herein. Also, additional steps may be performed before, after, and/or during method 2400.

Method 2400 includes operations S11-S13, which are common to method 10 and are described above in reference to FIGS. 1 and 3-5.

Cross-referencing FIG. 24 and FIGS. 25-26, method 2400 continues from operation S13 with forming openings 901 in a cut-poly process at operation S216. FIG. 25 is a Y-cut cross-sectional view taken along a gate 303, and FIG. 26 is an X-cut cross-sectional view taken along a fin 105.

Operation S216 may include patterning a mask (not shown) over the dummy gate 303 to expose the underlying materials in desired locations where cut-poly gate dielectric structures are to be formed. After being patterned, the mask is used as an etching mask to etch the underlying materials to form openings 901 (e.g., trenches, recesses, channels or the like). In the etching process, the material of the dummy gates 303 is etched using an anisotropic etching process. In certain embodiments, the etch process etches into the isolation regions 209. The openings 901 may be formed between adjacent fins 105 and may be formed to cut through one or more dummy gates 303. According to some embodiments, two of the openings 901 are formed to cut through two dummy gates 303 and are located on opposite sides of one or more of the fins 105, e.g., selected fin(s), as shown in FIG. 2. After the openings 901 have been formed, the masking layer may be removed.

As further shown in FIG. 24 and FIGS. 25-26, method 2400 may continue, at operation S217, with forming dielectric structures 110, such as dielectric pillars 110, from dielectric material 109, in accordance with some embodiments. In the illustrated embodiment, the dielectric pillars 110 are cut-poly gate dielectric structures 110.

Specifically, the dielectric pillars 110 are formed by initially depositing a dielectric material 109 to fill and overfill the openings 901. In accordance with some embodiments, the dielectric material 109 is formed using any dielectric material and deposition process suitable. In certain embodiments, dielectric material 109 may be silicon nitride (SiN) formed in a deposition process such as Atomic Layer Deposition (ALD). However, any suitable dielectric materials and deposition processes may be used. According to some embodiments, the dielectric pillars 110 are formed with a width between adjacent metal gate segments 108 of from about 5 nm to about 50 nm, such as about 10 nm. However, any suitable widths may be used.

As shown, the dielectric pillars 110 extend into the STI regions 209 and divide the dummy gates 303, which are relatively long, into a plurality of gates segments 108 which are relatively short. Furthermore, the excess dielectric material 109 of the dielectric pillars 110 outside of the openings 901 may be retained and used as a masking layer in the Continuous Poly On Diffusion Edge (CPODE) process.

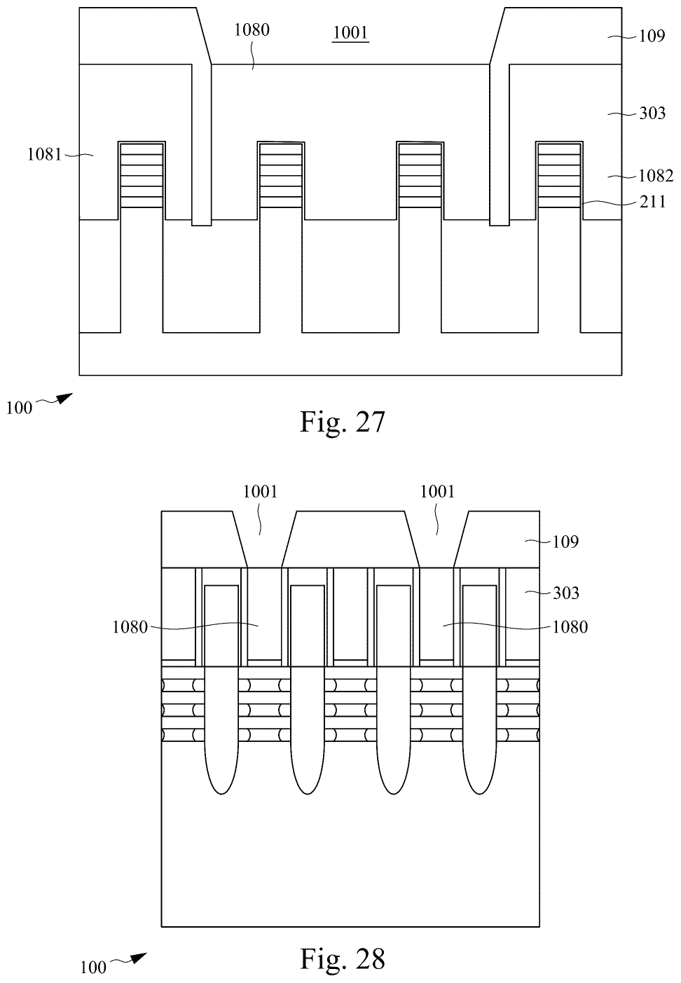

Cross-referencing FIG. 24 and FIGS. 27-28, method 2400 may continue at operation S218 with forming an opening 1001 in the dielectric material 109 over each segment 1080 of dummy gate 303 to be removed in an initial step of forming a Continuous Poly On Diffusion Edge (CPODE) structure, in accordance with some embodiments. The CPODE structure may also be referred to herein as an insulation feature or a cut-PODE structure and is discussed in greater detail with the following figures. FIG. 27 is a Y-cut cross-sectional view taken along a gate 303, similar to FIG. 25, and FIG. 28 is an X-cut cross-sectional view taken along a fin 105, similar to FIG. 26.

In certain embodiments, forming the opening 1001 in the dielectric material 109 may include depositing a variety of masking layers, such as including a carbon based bottom layer, an oxide based middle layer, and an extreme ultraviolet (EUV) photo resist top layer. The process may include performing an extreme ultraviolet lithography (EUV) photo resist exposure technique to pattern the photo resist, followed by etching of the middle layer and bottom layer. Then, the dielectric material 109 is etched to form the opening 1001. The dielectric material 109 may be etched by a dry etch process, such as a process suitable for etching a silicon nitride material.

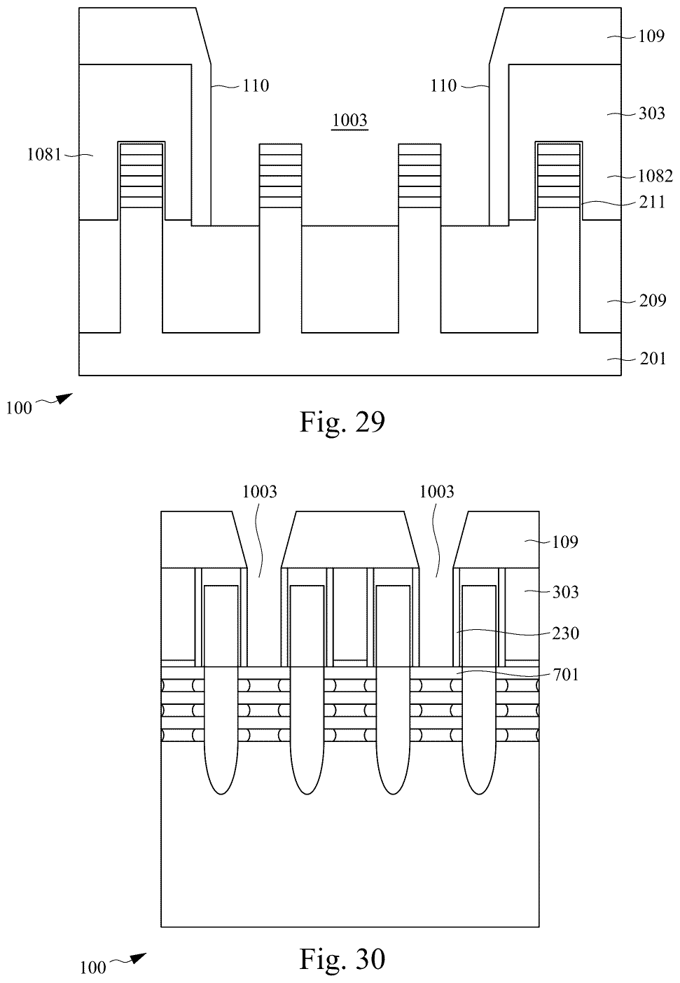

Cross-referencing FIGS. 24 and FIGS. 29 and 30, method 2400 may continue, at operation S219, with removing the dummy gate segments 1080. FIG. 29 is a Y-cut cross-sectional view taken along a gate 303, similar to FIG. 25, and FIG. 30 is an X-cut cross-sectional view taken along a fin 105, similar to FIG. 26.

In certain embodiments, removing each dummy gate segment 1080 forms an opening 1003 and includes selectively removing the dummy gate 303 and the dummy gate dielectric 211 in the dummy gate segment 1080.

In certain embodiments, the dummy gate 303 is removed by a dry etch selective to removing the material of the dummy gate 303, such as polysilicon. In certain embodiments, the dummy gate dielectric 211 is then removed by a dry etch selective to removing the material of the dummy gate dielectric 211, such as silicon oxide. Wet clean processes may be performed after each dry etch process.

In certain embodiments, the process may remove all of the dummy gate segment 1080 between the dielectric pillars 110 and over the STI regions 209, as shown in FIG. 29. Further, the process may remove all of the dummy gate segment 1080 between the sidewall spacers 1004 and over the uppermost nanosheet 701, as shown in FIG. 30.

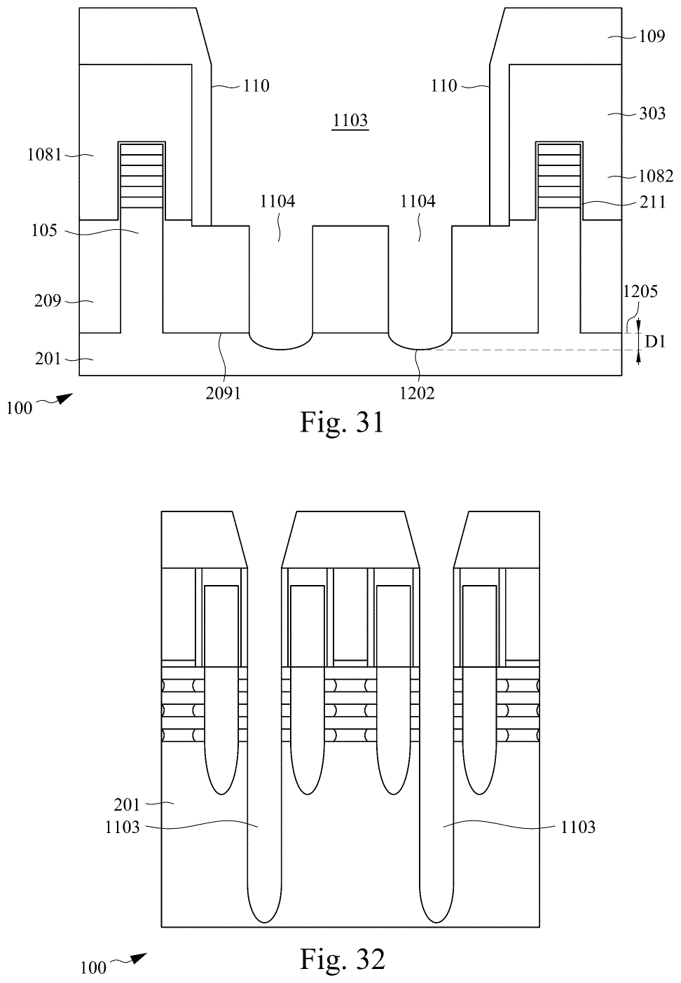

Cross-referencing FIG. 24 and FIGS. 31 and 32, method 2400 may continue, at operation S220, with removing the nanostructures 701 and recessing the selected fins 105 to form opening 1103. FIG. 31 is a Y-cut cross-sectional view taken along a gate 303, similar to FIG. 25, and FIG. 32 is an X-cut cross-sectional view taken along a fin 105, similar to FIG. 26.

Specifically, after uncovering the nanostructures 701 and a portion of the fins 105 protruding above the isolation regions 209, a further etching process may be used to remove the materials of the nanostructures 701 and to recess the fins 105. In certain embodiments, the uncovered fins 105 are removed, and a portion of the underlying substrate 201 is etched. As a result, an upper surface of the substrate 201 is recessed to a recessed surface 1202 at a depth D1 from the upper surface 1205 of the substrate 201 or bottom surface 2091 of STI region 209. The recessed surface 1202 may be considered to be cavity bottom surface 1202. As shown, the opening 1103 includes projections or fin cavities 1104 that extend through the STI region 209 to the recessed surface 1202.

In certain embodiments, the etch process is a plasma etch.

After the nanostructures 701 have been removed and the portion of the fin 105 protruding above the isolation regions 209 has been recessed, the photo resist, if present, may be removed, for example, via an ashing process.

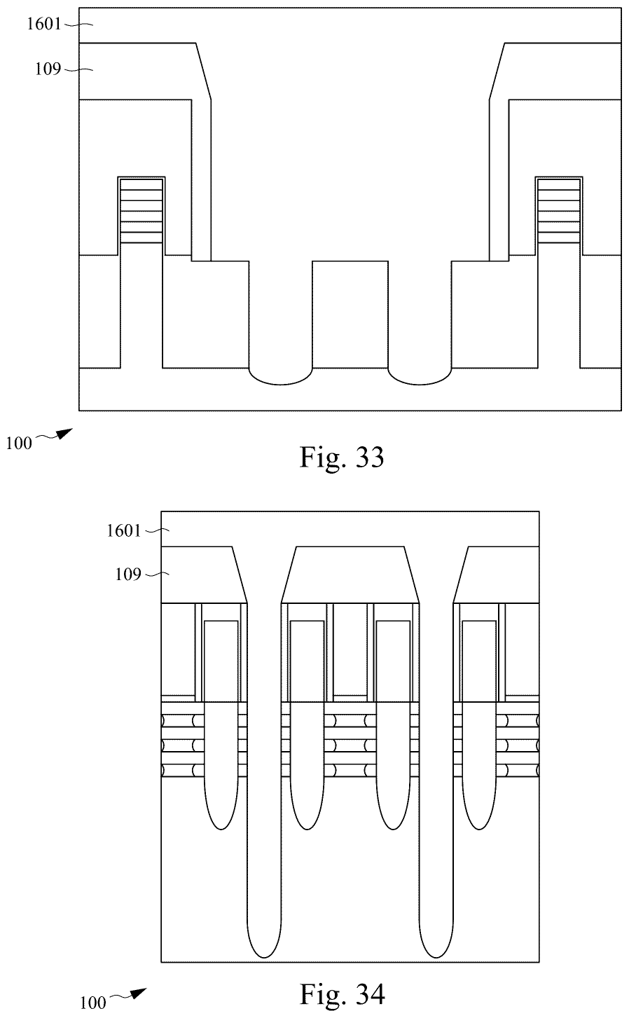

Cross-referencing FIG. 24 and FIGS. 33 and 34, method 2400 may continue, at operation S221, with forming a first insulating dielectric material 1601 in the opening 1103. FIG. 33 is a Y-cut cross-sectional view taken along a gate 303, similar to FIG. 25, and FIG. 34 is an X-cut cross-sectional view taken along a fin 105, similar to FIG. 26.

As shown in FIGS. 33 and 34, the first insulating dielectric material 1601 may completely fill the openings 1103.

In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is silicon oxide.

In certain embodiments, the first insulating dielectric material 1601 may be deposited with a refill process. In one example, the dielectric structure 1601 may be deposited by chemical vapor deposition (CVD), atomic layer deposition (ALD), spin-on coating, or other suitable techniques. As shown, the first insulating dielectric material 1601 may be first formed as a blanket layer covering the surface of the dielectric material 109.

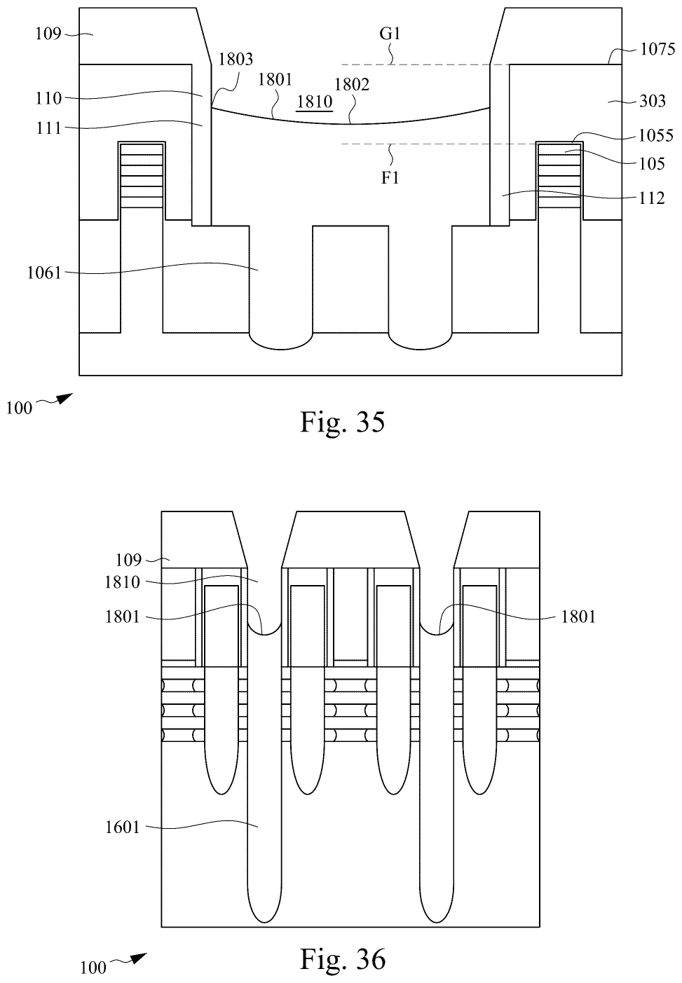

Cross-referencing FIG. 24 and FIGS. 35 and 36, method 2400 may continue, at operation S222, with recessing the first insulating dielectric material 1601 to form a recess or opening 1810. FIG. 35 is a Y-cut cross-sectional view taken along a gate 303, similar to FIG. 25, and FIG. 36 is an X-cut cross-sectional view taken along a fin 105, similar to FIG. 26.

As shown in FIGS. 35 and 36, the first insulating dielectric material 1601 is recessed to a recessed surface 1801. The recessed surface 1801 extends laterally between dielectric pillars 110. Specifically, the recessed surface 1801 contacts a first dielectric pillar 111 and an adjacent second dielectric pillar 112.

As shown, the dummy gate 303 has an uppermost surface 1075 that defines an upper gate plane G1.

In certain embodiments, the recessed surface 1801 has a lowest point 1802 at a height below the upper gate plane G1. In certain embodiments, the recessed surface 1801 contacts the first dielectric pillar 111 at a height below the upper gate plane G1. In certain embodiments, the recessed surface 1801 contacts the second dielectric pillar 112 at a height below the upper gate plane G1. In certain embodiments, the recessed surface 1801 has an uppermost point 1803, such as at the interface with the first dielectric pillar 111 or with the second dielectric pillar 112, at a height below the upper gate plane G1. In certain embodiments, the entirety of the recessed surface 1801 is at a height below the upper gate plane G1. As used herein, a point at a height below the upper gate plane G1 is located between the upper gate plane G1 and the substrate 201.

As shown, each fin 105 has an uppermost surface 1055 that defines an upper gate plane F1.

In certain embodiments, the lowest point 1802 of the recessed surface 1801 is at a height above the upper fin plane F1. In certain embodiments, the recessed surface 1801 contacts the first dielectric pillar 111 at a height above the upper fin plane F1. In certain embodiments, the recessed surface 1801 contacts the second dielectric pillar 112 at a height above the upper fin plane F1. In certain embodiments, the recessed surface 1801 has an uppermost point 1803, such as at the interface with the first dielectric pillar 111 or with the second dielectric pillar 112, at a height above the upper fin plane F1. In certain embodiments, the entirety of the recessed surface 1801 is at a height above the upper fin plane F1. As used herein, a point at a height above the fin plane F1 is located such that the fin plane F1 is between point and the substrate 201.

Cross-referencing FIG. 24 and FIGS. 37 and 38, method 2400 may continue, at operation S223, with depositing a second insulating dielectric material 2001 in the opening 1810 over the first insulating dielectric material 1601. FIG. 27 is a Y-cut cross-sectional view taken along a gate 303, similar to FIG. 25, and FIG. 38 is an X-cut cross-sectional view taken along a fin 105, similar to FIG. 26.

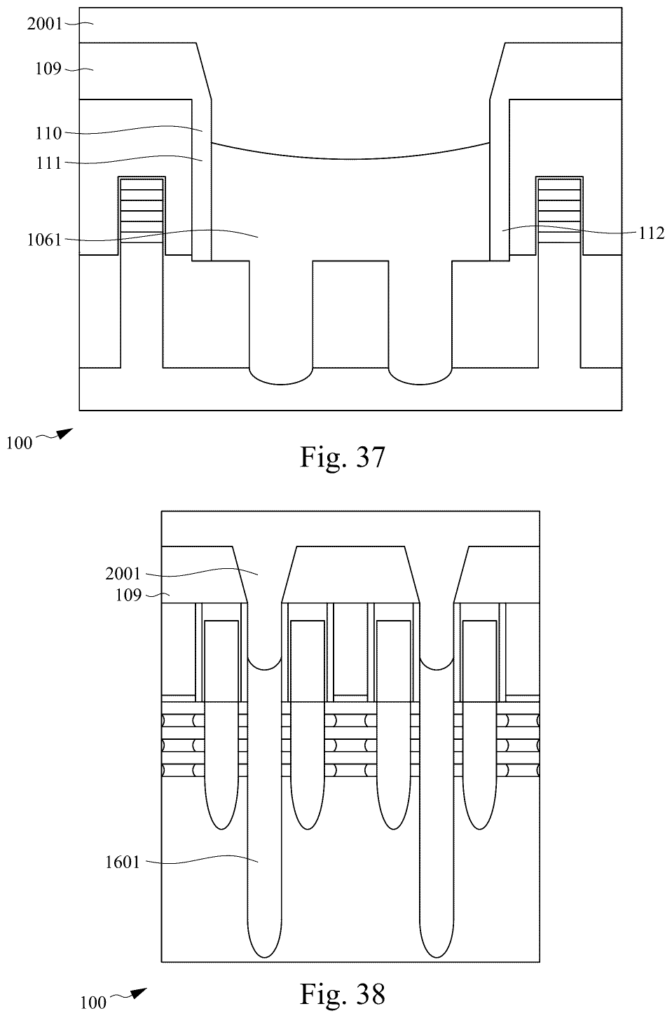

As shown in FIGS. 37 and 38, the second insulating dielectric material 2001 may completely fill the openings 1810.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

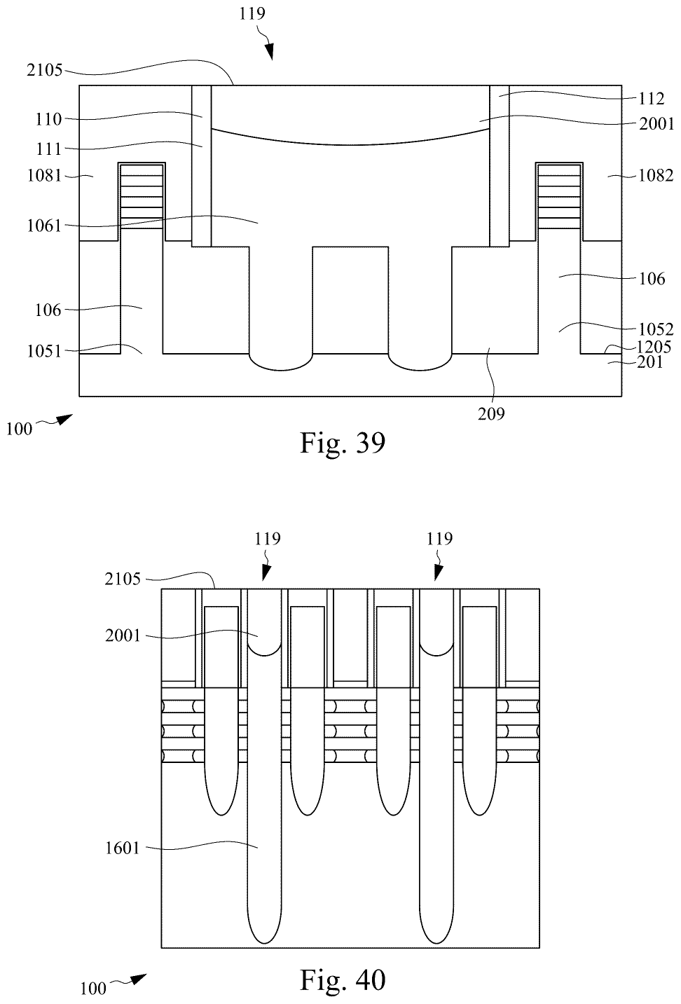

Cross-referencing FIG. 24 and FIGS. 39 and 40, method 2400 may continue, at operation S224, with planarizing the structure of device 100. FIG. 39 is a Y-cut cross-sectional view taken along a gate 303, similar to FIG. 25, and FIG. 40 is an X-cut cross-sectional view taken along a fin 105, similar to FIG. 26.

As shown in FIGS. 39 and 40, the planarization process may remove all of the overburden portion of the dielectric material 109 and all of the overburden portion of the second insulating dielectric material 2001 and form the structure of device 100 with an upper surface 2101 formed by the first dummy gate segment 1081, dielectric pillar 111, second insulating dielectric material 2001, dielectric pillar 112 and second dummy gate segment 1082.

Operation S224 may be considered to complete the CPODE process by forming the insulation feature 119 in the form of a CPODE structure, include bottom layer or first insulating dielectric material 1601 and top layer or second insulating dielectric material 2001. As shown, each of the first insulating dielectric material 1601 and top layer or second insulating dielectric material 2001 contacts the first dielectric pillar 111 and the second dielectric pillar 112 such that the first insulating dielectric material 1601 is completely covered by, and encapsulated by, the second insulating dielectric material 2001.

As shown in FIG. 24, the method 2400 may continue with performing a replacement metal gate process at operation S225. For example, processing according to operations S14 and S15 of method 10 may be performed to form a metal gate.

As shown in FIG. 24, method 2400 may continue, at operation S226, with further processing for completing the device 100. For example, the further processing may include forming interlayer dielectric and metallization layers, forming source/drain contacts to the source/drain regions, and forming source/drain vias and gate vias, in accordance with some embodiments.

Thus, FIGS. 24-40 provide a method for forming a device 100 with an insulation feature 119 before replacing the dummy gate 303 with a metal gate 107.

In the embodiments of FIGS. 24-40, a cut metal gate in the form of a cut-dummy gate dielectric structure or cut-poly gate dielectric structure is formed before the CPODE insulation feature 119. However, certain embodiments may avoid use of a cut metal gate dielectric structures. For example, devices with extreme scaling may not include cut metal gate dielectric structures.

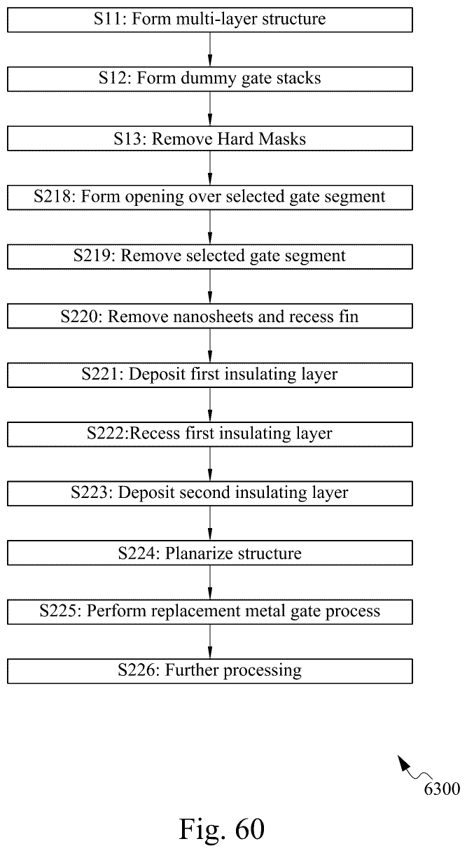

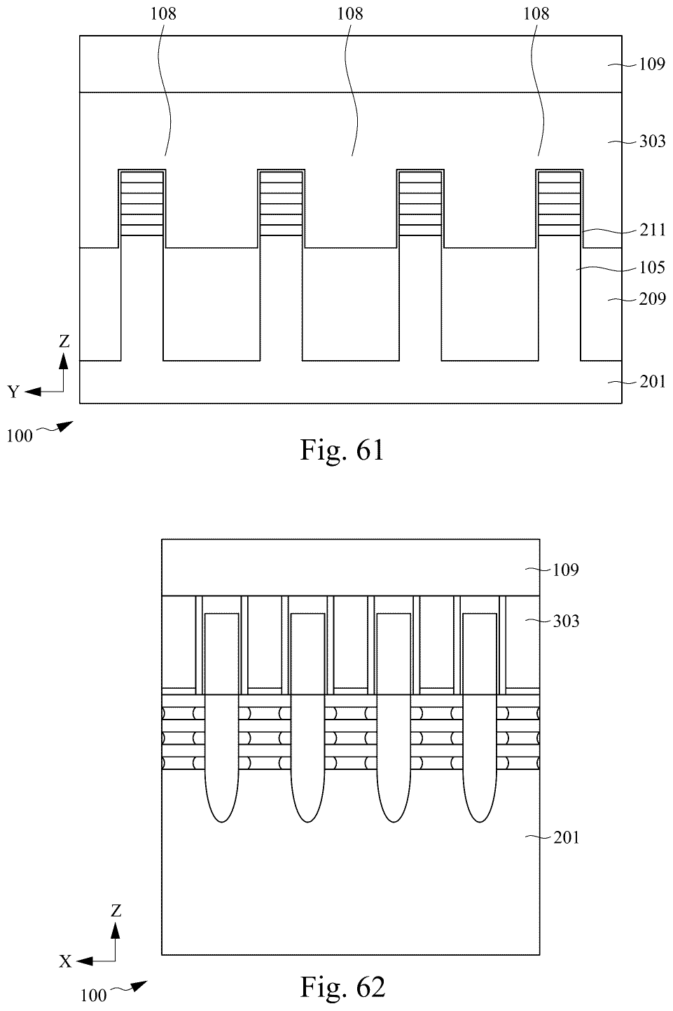

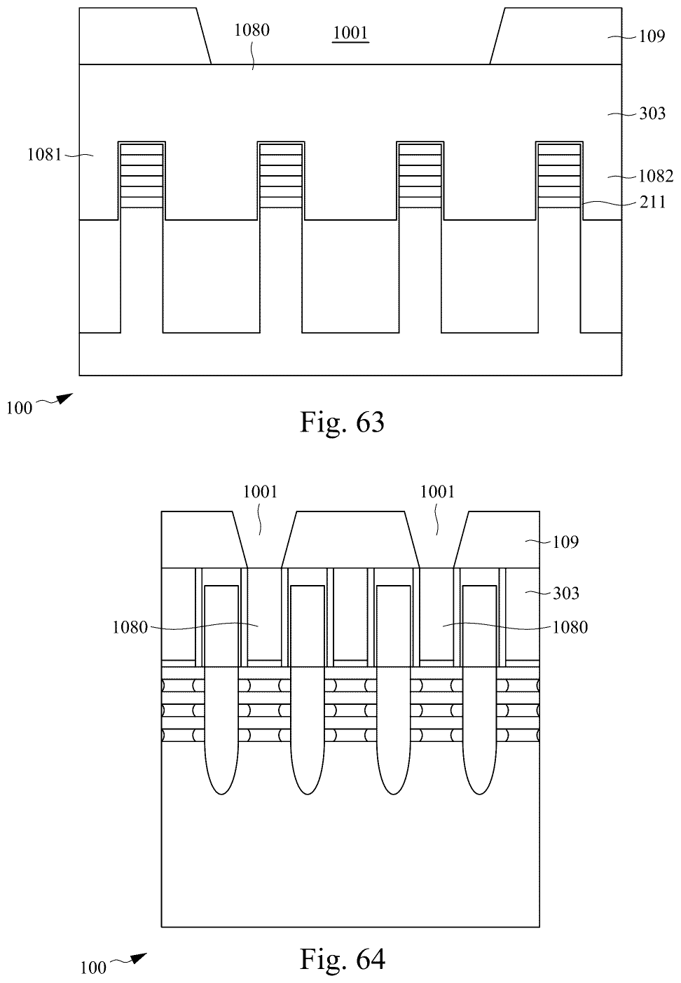

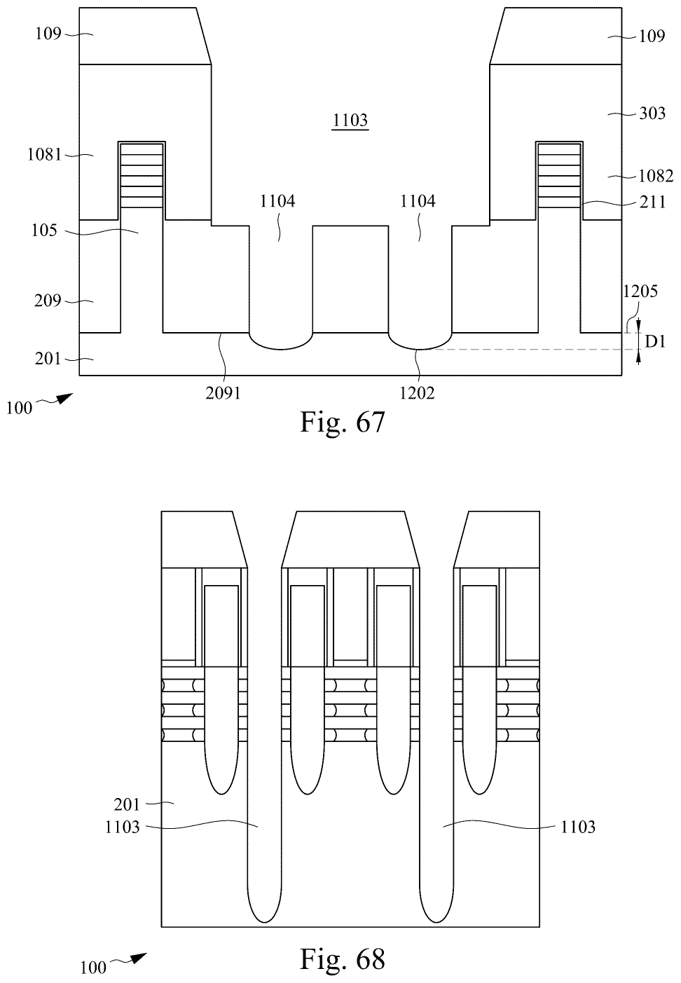

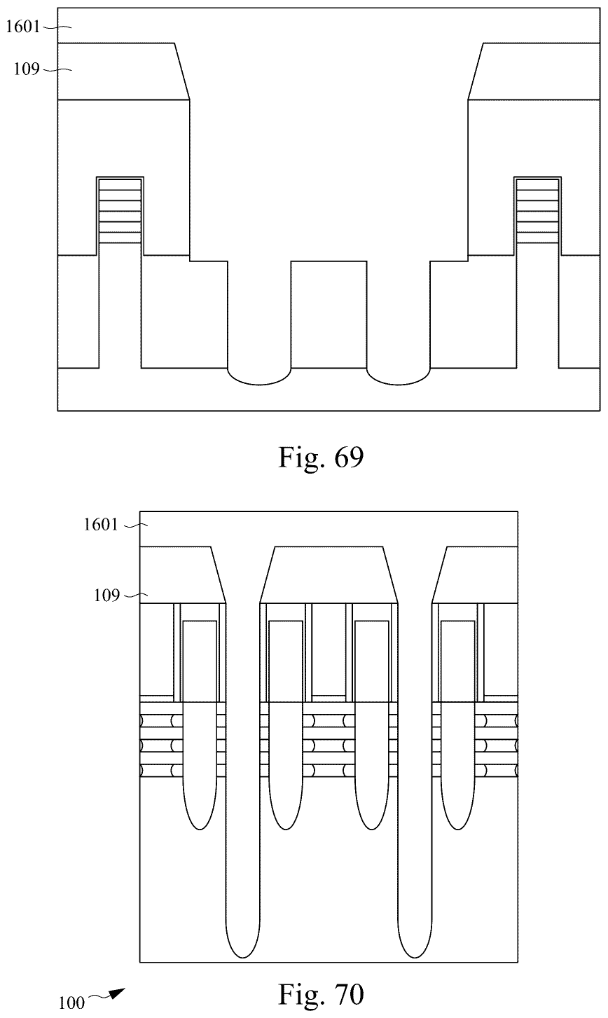

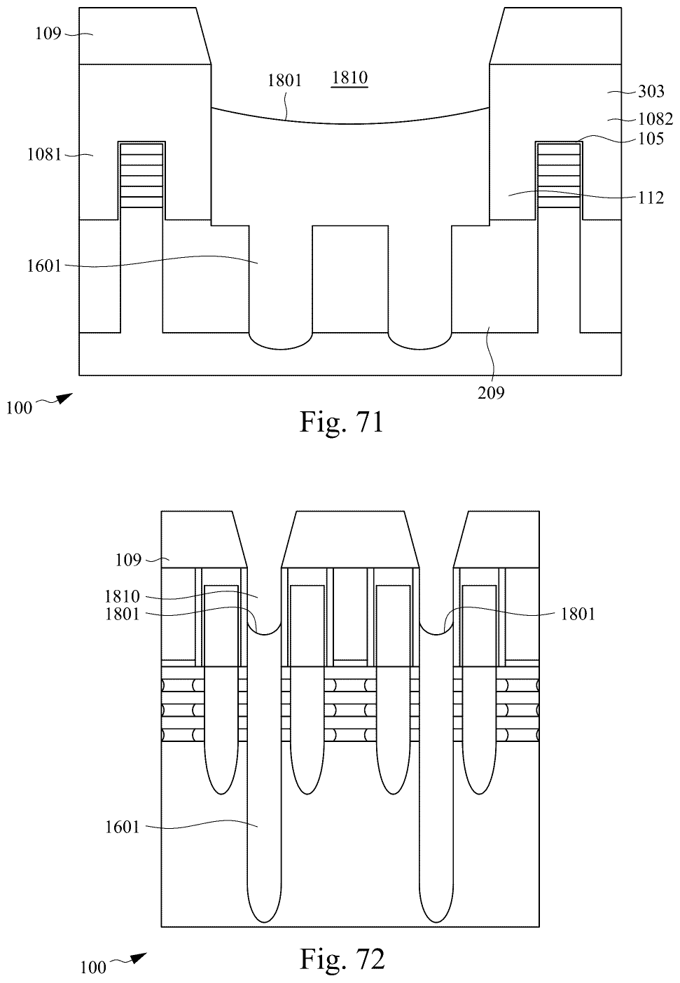

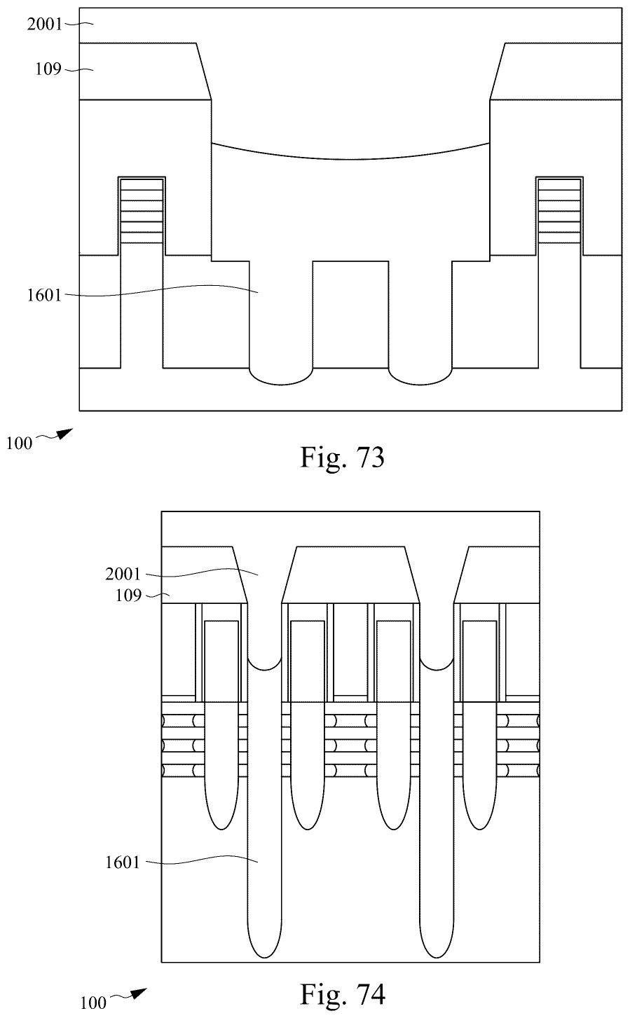

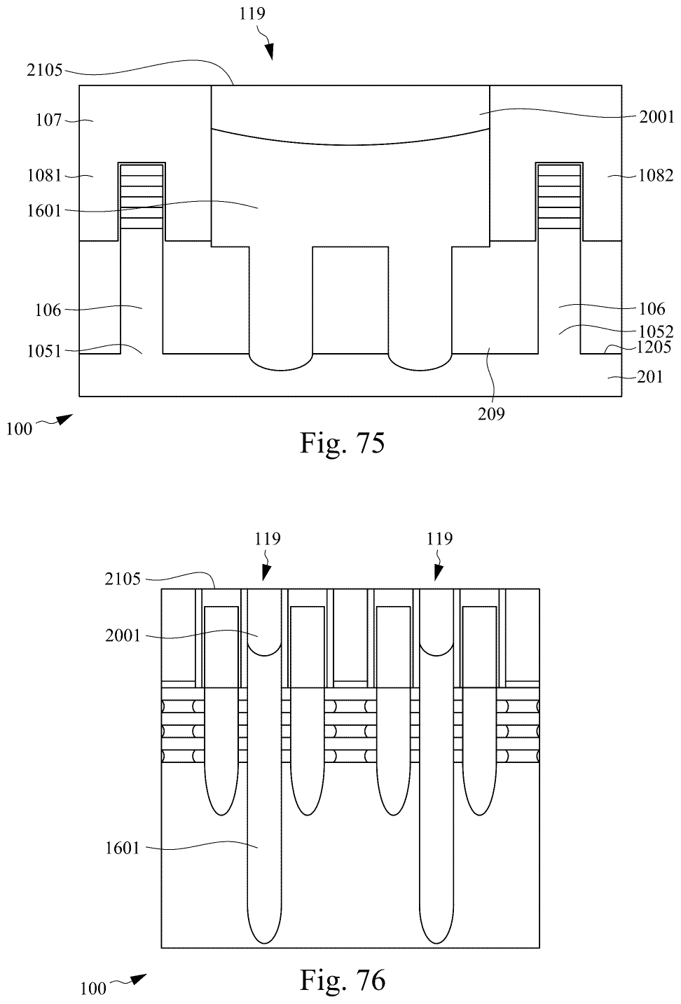

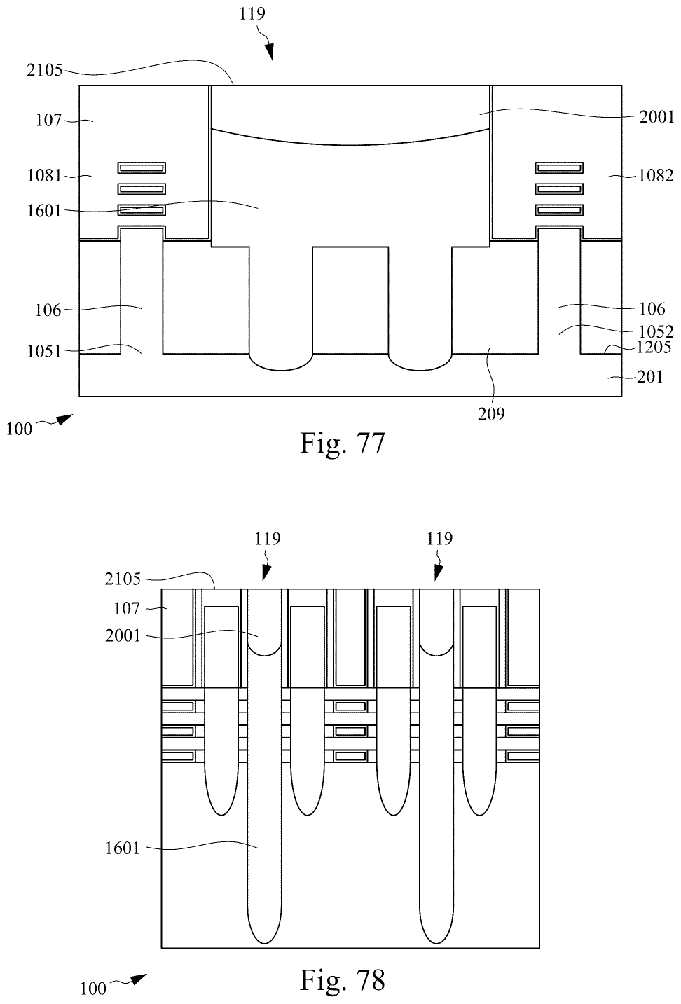

FIG. 60 illustrates embodiments of a method 6300 that forms an insulation features as a CPODE insulation feature 119 without use of cut metal gate dielectric structures. Method 6300 is described below with reference to FIGS. 2 and 61-78 which illustrate the semiconductor device 100 at various stages of fabrication according to method 6300. FIG. 2 illustrates a top-down view of an intermediate structure in forming a device 100, such as a gate-all-around (GAA) semiconductor device, according to some embodiments. FIGS. 61, 63, 65, 67, 69, 71, 73, 75, and 77 are cross-sectional views in which the vertical direction is defined by the Z-axis and the lateral direction is defined by the Y-axis. FIGS. 62, 64, 66, 68, 70, 72, 74, 76, and 78 are cross-sectional views in which the vertical direction is defined by the Z-axis and the lateral direction is defined by the X-axis and each view illustrates the same stage of fabrication as the immediately preceding figure.

It is understood that method 6300 includes steps having features of a complementary metal-oxide-semiconductor (CMOS) technology process flow and thus, are only described briefly herein. Also, additional steps may be performed before, after, and/or during method 6300.

Method 6300 includes operations S11-S13, which are common to method 10 and are described above in reference to FIGS. 1 and 3-5.

Cross-referencing FIG. 60 and FIGS. 61-62, after operation S13, dielectric material 109 may be formed over the device 100.

Cross-referencing FIG. 60 and FIGS. 63-64, method 6300 continues at S218 may continue at operation S218 with forming an opening 1001 in the dielectric material 109 over each segment 1080 of dummy gate 303 to be removed in an initial step of forming a Continuous Poly On Diffusion Edge (CPODE) structure, in accordance with some embodiments. The CPODE structure may also be referred to herein as an insulation feature or a cut-PODE structure and is discussed in greater detail with the following figures.

In certain embodiments, forming the opening 1001 in the dielectric material 109 may include depositing a variety of masking layers, such as including a carbon based bottom layer, an oxide based middle layer, and an extreme ultraviolet (EUV) photo resist top layer. The process may include performing an extreme ultraviolet lithography (EUV) photo resist exposure technique to pattern the photo resist, followed by etching of the middle layer and bottom layer. Then, the dielectric material 109 is etched to form the opening 1001. The dielectric material 109 may be etched by a dry etch process, such as a process suitable for etching a silicon nitride material.

Cross-referencing FIGS. 60 and FIGS. 65 and 66, method 6300 may continue, at operation S219, with removing the dummy gate segments 1080. In certain embodiments, removing each dummy gate segment 1080 forms an opening 1003 and includes selectively removing the dummy gate 303 and the dummy gate dielectric 211 in the dummy gate segment 1080.

In certain embodiments, the dummy gate 303 is removed by a dry etch selective to removing the material of the dummy gate 303, such as polysilicon. In certain embodiments, the dummy gate dielectric 211 is then removed by a dry etch selective to removing the material of the dummy gate dielectric 211, such as silicon oxide. Wet clean processes may be performed after each dry etch process.

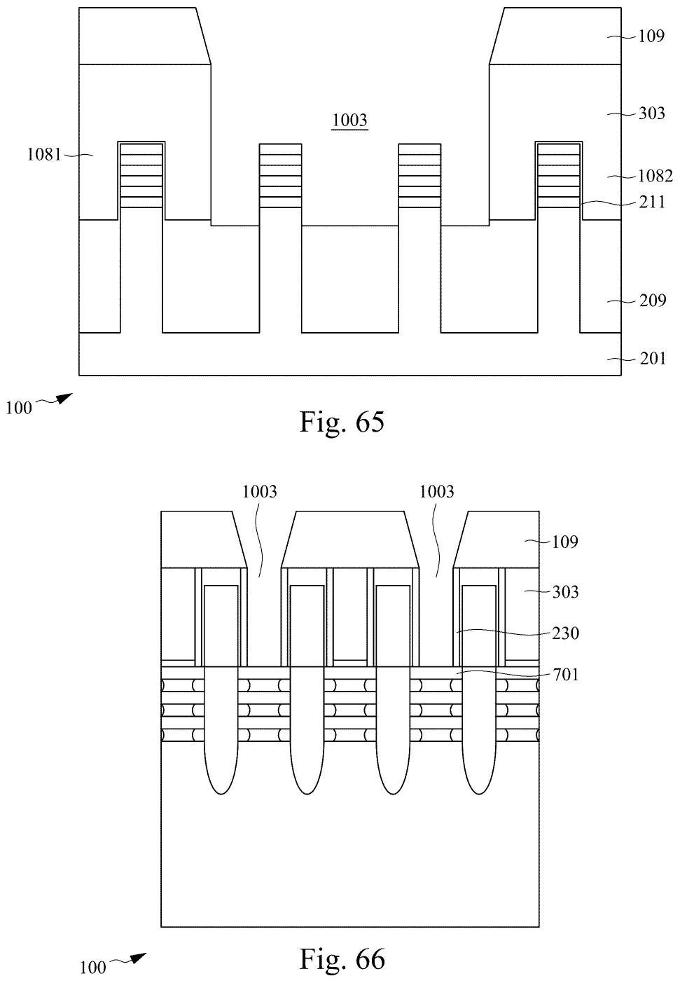

In certain embodiments, the process may remove all of the dummy gate segment 1080 between the sidewall spacers 1004 and over the uppermost nanosheet 701, as shown in FIG. 66.

Cross-referencing FIG. 60 and FIGS. 67 and 68, method 6300 may continue, at operation S220, with removing the nanostructures 701 and recessing the selected fins 105 to form opening 1103. Specifically, after uncovering the nanostructures 701 and a portion of the fins 105 protruding above the isolation regions 209, a further etching process may be used to remove the materials of the nanostructures 701 and to recess the fins 105. In certain embodiments, the uncovered fins 105 are removed, and a portion of the underlying substrate 201 is etched. As a result, an upper surface of the substrate 201 is recessed to a recessed surface 1202 at a depth D1 from the upper surface 1205 of the substrate 201 or bottom surface 2091 of STI region 209. The recessed surface 1202 may be considered to be cavity bottom surface 1202. As shown, the opening 1103 includes projections or fin cavities 1104 that extend through the STI region 209 to the recessed surface 1202. In certain embodiments, the etch process is a plasma etch.

After the nanostructures 701 have been removed and the portion of the fin 105 protruding above the isolation regions 209 has been recessed, the photo resist, if present, may be removed, for example, via an ashing process.

Cross-referencing FIG. 60 and FIGS. 69 and 70, method 6300 may continue, at operation S221, with forming a first insulating dielectric material 1601 in the opening 1103. As shown, the first insulating dielectric material 1601 may completely fill the openings 1103. In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is silicon oxide.

In certain embodiments, the first insulating dielectric material 1601 may be deposited with a refill process. In one example, the dielectric structure 1601 may be deposited by chemical vapor deposition (CVD), atomic layer deposition (ALD), spin-on coating, or other suitable techniques. As shown, the first insulating dielectric material 1601 may be first formed as a blanket layer covering the surface of the dielectric material 109.

Cross-referencing FIG. 60 and FIGS. 71 and 72, method 6300 may continue, at operation S222, with recessing the first insulating dielectric material 1601 to form a recess or opening 1810. As shown, the first insulating dielectric material 1601 is recessed to a recessed surface 1801. The recessed surface 1801 extends laterally between and contacts gate segments 1081 and 1082.

Cross-referencing FIG. 60 and FIGS. 73 and 74, method 6300 may continue, at operation S223, with depositing a second insulating dielectric material 2001 in the opening 1810 over the first insulating dielectric material 1601. As shown, the second insulating dielectric material 2001 may completely fill the openings 1810.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

Cross-referencing FIG. 60 and FIGS. 75 and 76, method 6300 may continue, at operation S224, with planarizing the structure of device 100. As shown, the planarization process may remove all of the overburden portion of the dielectric material 109 and all of the overburden portion of the second insulating dielectric material 2001 and form the structure of device 100 with an upper surface 2101 formed by the first dummy gate segment 1081, second insulating dielectric material 2001, and second dummy gate segment 1082.

Operation S224 may be considered to complete the CPODE process by forming the insulation feature 119 in the form of a CPODE structure, include bottom layer or first insulating dielectric material 1601 and top layer or second insulating dielectric material 2001. As shown, each of the first insulating dielectric material 1601 and top layer or second insulating dielectric material 2001 contacts the first gate segment 1081 and the second gate segment 1082 such that the first insulating dielectric material 1601 is completely covered by, and encapsulated by, the second insulating dielectric material 2001.

Cross-referencing FIG. 60 and FIGS. 77 and 78, method 6300 may continue with performing a replacement metal gate process at operation S225. For example, processing according to operations S14 and S15 of method 10 may be performed to form the metal gate 107.

As shown in FIG. 60, method 2000 may continue, at operation S226, with further processing for completing the device 100. For example, the further processing may include forming interlayer dielectric and metallization layers, forming source/drain contacts to the source/drain regions, and forming source/drain vias and gate vias, in accordance with some embodiments.

Thus, FIGS. 60-78 provide a method for forming a device 100 with an insulation feature 119 before replacing the dummy gate 303 with a metal gate 107.

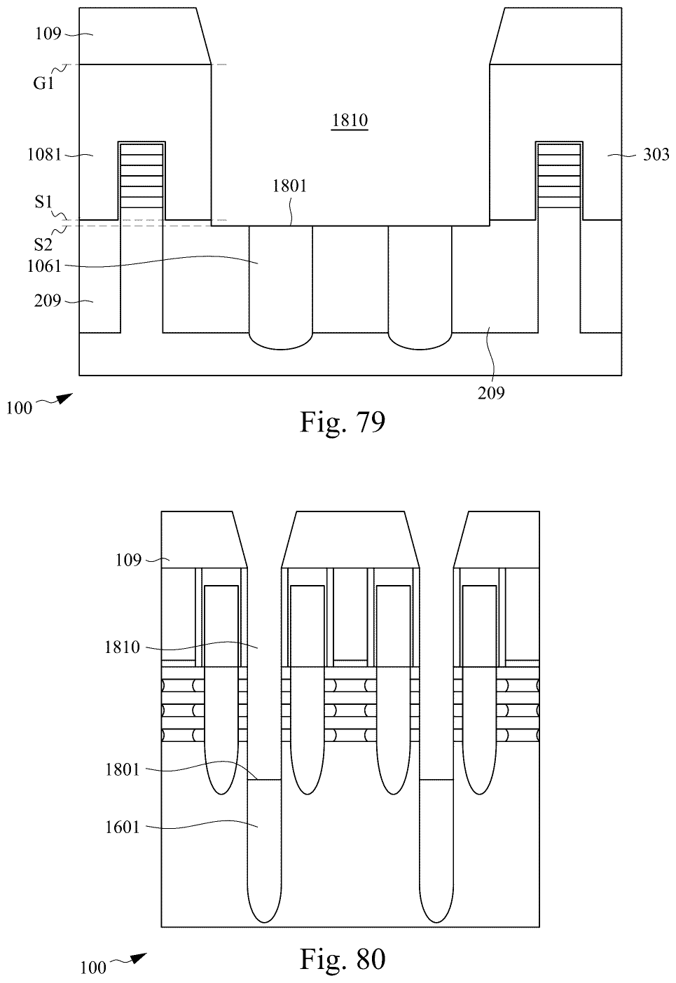

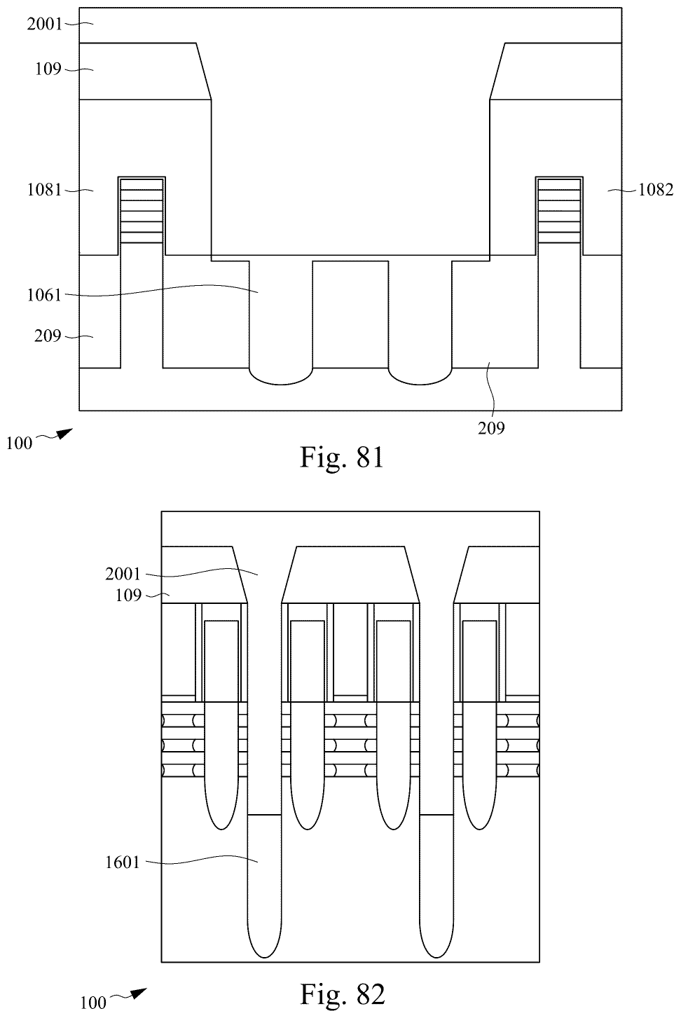

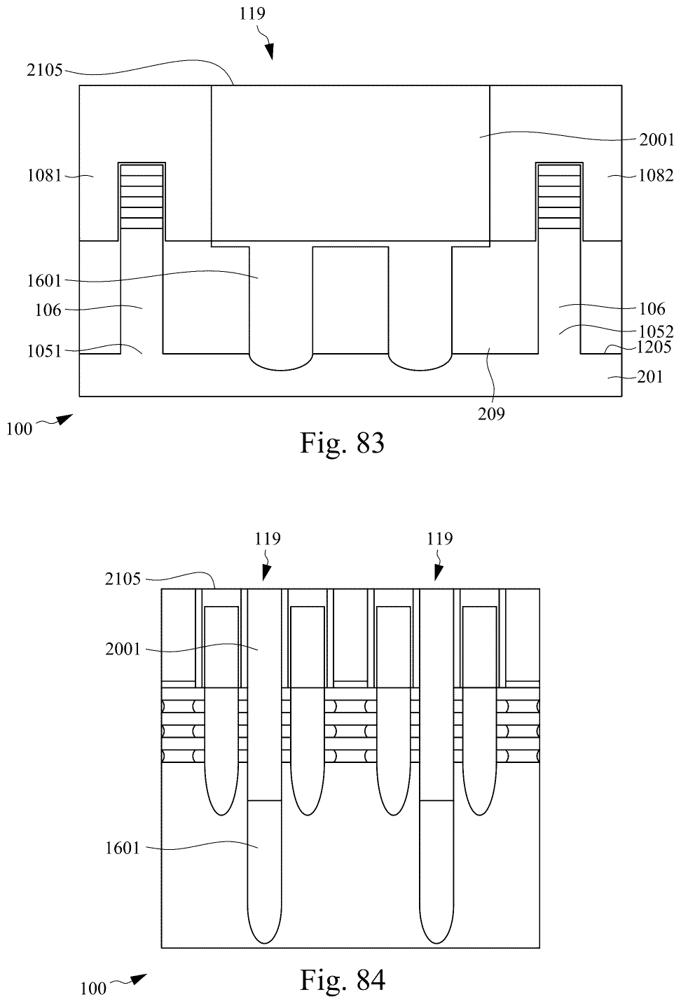

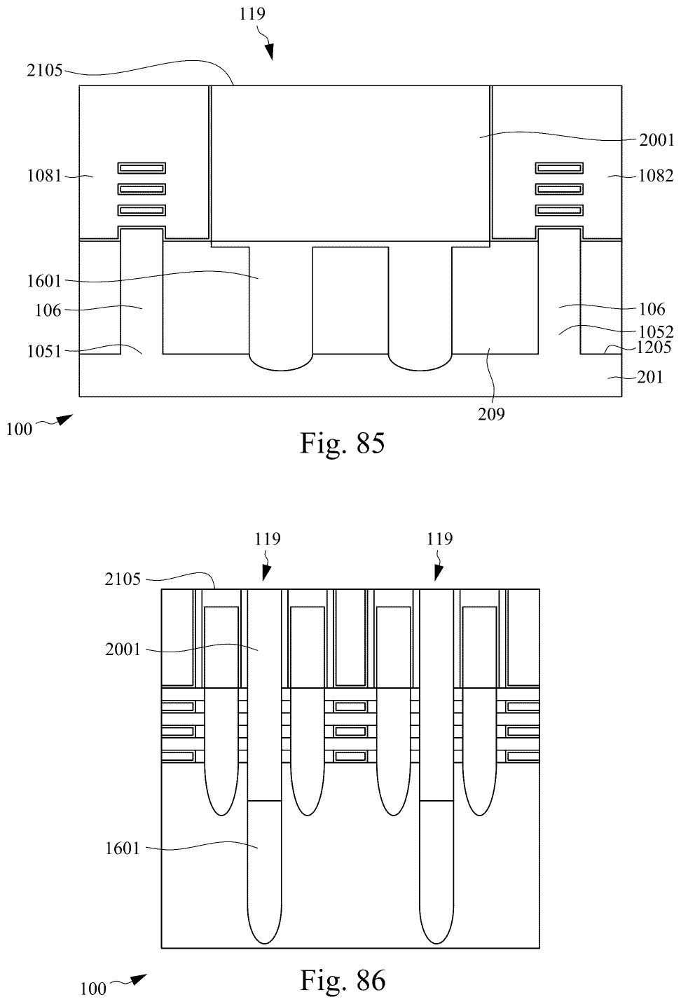

FIGS. 79-86 illustrate an alternative embodiment of method 6300. FIGS. 79, 81, 83, and 85 are cross-sectional views in which the vertical direction is defined by the Z-axis and the lateral direction is defined by the Y-axis. FIGS. 80, 82, 84, and 86 are cross-sectional views in which the vertical direction is defined by the Z-axis and the lateral direction is defined by the X-axis and each view illustrates the same stage of fabrication as the immediately preceding figure.

Cross-referencing FIG. 60 and FIGS. 79 and 80, method 6300 may continue, at operation S222, with recessing the first insulating dielectric material 1601 to form a recess or opening 1810. As shown, the first insulating dielectric material 1601 is recessed to a recessed surface 1801. The recessed surface 1801 extends laterally between and contacts the STI region 209 below gate segments 1081 and 1082. Specifically, the upper surface of the STI region 209, forming an interface with the dummy gate 303, is located at a plane S1 and the upper surface 1801 of the material 1601 is located at a plane S2 located below the plane S1. In other words, plane S1 is located between plane S2 and the upper gate plane G1.

Cross-referencing FIG. 60 and FIGS. 81 and 82, method 6300 may continue, at operation S223, with depositing a second insulating dielectric material 2001 in the opening 1810 over the first insulating dielectric material 1601. As shown, the second insulating dielectric material 2001 may completely fill the openings 1810.

In the embodiment of FIGS. 79-86, the second insulating dielectric material 2001 extends between and contacts the STI region 209. As a result, the second insulating dielectric material 2001 forms a barrier between the sidewalls of the gate segments 1081 and 1082 and the first insulating dielectric material 1601.

Cross-referencing FIG. 60 and FIGS. 83 and 84, method 6300 may continue, at operation S224, with planarizing the structure of device 100. As shown, the planarization process may remove all of the overburden portion of the dielectric material 109 and all of the overburden portion of the second insulating dielectric material 2001 and form the structure of device 100 with an upper surface 2101 formed by the first dummy gate segment 1081, second insulating dielectric material 2001, and second dummy gate segment 1082.

Operation S224 may be considered to complete the CPODE process by forming the insulation feature 119 in the form of a CPODE structure, include bottom layer or first insulating dielectric material 1601 and top layer or second insulating dielectric material 2001. As shown, the first insulating dielectric material 1601 does not contact the first gate segment 1081 and the second gate segment 1082. The top layer or second insulating dielectric material 2001 contacts the first gate segment 1081 and the second gate segment 1082 such that the first insulating dielectric material 1601 is completely covered by, and encapsulated by, the second insulating dielectric material 2001 within the STI region 209.

Cross-referencing FIG. 60 and FIGS. 85 and 86, method 6300 may continue with performing a replacement metal gate process at operation S225. For example, processing according to operations S14 and S15 of method 10 may be performed to form the metal gate 107. Because the first insulating dielectric material 1601 is separated from the gate segments 1081 and 1082 by the STI region 209 and the second insulating dielectric material 2001 during replacement of the dummy gate material with metal gate material, negative interactions between an oxide dielectric material 1601 and metal are avoided.

As shown in FIG. 60, method 2000 may continue, at operation S226, with further processing for completing the device 100. For example, the further processing may include forming interlayer dielectric and metallization layers, forming source/drain contacts to the source/drain regions, and forming source/drain vias and gate vias, in accordance with some embodiments.

Thus, FIGS. 60-70 and 79-86 provide a method for forming a device 100 with an insulation feature 119 before replacing the dummy gate 303 with a metal gate 107.

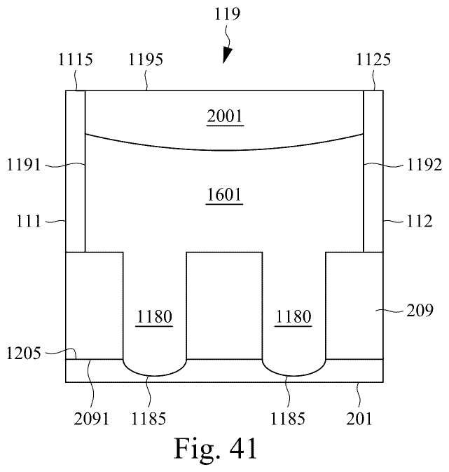

Referring back to FIGS. 22 and 39, it may be seen that the CMODE process and the CPODE process may form the insulation feature 119 with similar structures. FIG. 41 presents a focused view of the insulation feature 119 of FIGS. 22 and 39.

Cross-referencing FIGS. 22, 39 and 41, semiconductor device 100 includes a first fin structure 1051 located over substrate 201; a first gate segment 1081 located over first fin structure 1051; a second fin structure 1052 located over substrate 201; a second gate segment 1082 located over second fin structure 1052; and an insulation feature 119 located between the first fin structure 1051 and the second fin structure 1052 and located between the first gate segment 1081 and the second gate segment 1082. As shown, insulation feature 119 extends laterally from a first sidewall 1191 nearest the first gate segment 1081 to a second sidewall 1192 nearest the second gate segment 1082.

In the illustrated embodiment, insulation feature 119 includes a bottom layer 1601 of silicon oxide and a top layer 2001 of silicon nitride located over the bottom layer 1601 of silicon oxide. As shown, the top layer 2001 of silicon nitride forms an uppermost surface 1195 of the insulation feature 119.

As shown, the semiconductor device 100 includes a shallow trench isolation (STI) region 209 overlying the upper surface 1205 of the substrate 201 and laterally adjacent to base portions 106 of the fin structures 1051 and 1052. The insulation feature includes a projection or projections 1180 that extend through the STI region 209 to a lowest surface 1185 of the insulation feature 119. Cross-referencing FIG. 41 with FIGS. 14 and 31, the lowest surface 1185 is located at a distance D1 from the upper surface 1205 of the substrate 201 (or bottom surface 2091 of STI region 209). In certain embodiments, the distance D1 is less than 10 nm, such as less than 9 nm, less than 8 nm, less than 7 nm, less than 6 nm, less than 5 nm, less than 4 nm, less than 3 nm, less than 2 nm, less than 1 nm, less than 0.5 nm, or less than 0.1 nm. In certain embodiments, the distance D1 is near zero to avoid altering electrical properties of wells formed in the substrate 201, or no projections 1180 are present.

Referring back to FIGS. 22, 39 and 41, in the illustrated embodiments, the projection(s) 1180 extending through the STI region 209 are formed by the bottom layer 1601 of silicon oxide.

In certain embodiments, the device 100 includes a shallow trench isolation (STI) region 209 laterally adjacent to base portions 106 of the fin structures 1051 and 1052; a first dielectric pillar 111 extending vertically from the uppermost surface 1195 of the insulation feature 119 to the STI region 209; and a second dielectric pillar 112 extending vertically from the uppermost surface 1195 of the insulation feature 119 to the STI region 209. In such embodiments, the first sidewall 1191 of the insulation feature 119 contacts the first dielectric pillar 111 and the second sidewall 1192 of the insulation feature 119 contacts the second dielectric pillar 112.

As described in the CPODE process of FIGS. 24-40, the first dielectric pillar 111 may be a first cut gate dielectric; the second dielectric pillar 112 may be a second cut gate dielectric; an uppermost surface 1195 of the insulation feature 119 contacts an uppermost surface 1115 of the first cut gate dielectric 111 and an uppermost surface 1125 of the second cut gate dielectric 112. Further, the uppermost surface 1195 of the insulation feature 119 is formed by the top layer 2001 of silicon nitride such that the bottom layer 1601 of silicon oxide is encapsulated by the top layer 2001 of silicon nitride, the first cut gate dielectric 111 and the second cut gate dielectric 112. In certain embodiments, an interface is defined between the bottom layer 1601 of silicon oxide and the top layer 2001 of silicon nitride at the recessed surface 1801. Thus, recessed surface 1801 and the interface are the same and reference number 1801 may refer to either. In certain embodiments, interface 1801 contacts the first cut gate dielectric 111 and the second cut gate dielectric 112.

Referring to FIGS. 18, 35, and 41, in certain embodiments, interface 1801 is located at an interface height above the substrate; the interface 1801 contacts the first cut gate dielectric 111 and the second cut gate dielectric 112; an uppermost surfaces 1055 of the first fin structure and of the second fin structure define an uppermost fin plane F1; and the uppermost fin plane F1 is located between the interface height and the substrate 201.

In method 10 and method 2400, the gate is cut and the dielectric structures are formed before the insulation feature 119 is formed. As a result, the material of the insulation feature 119 is separated from the metal gate segments 1081 and 1082, and damage to the metal gate material is avoided. In method 10 and method 2400, silicon oxide may be used as the first insulating material 1601 to improve the quality of the interface of the insulation feature 119 and to minimize parasitic capacitance.

In method 10 and method 2400, the insulating layers 1601 and 2001 are vertically stacked, rather than horizontally stacked, i.e., the bottom layer 1601 is completely covered by the top layer 2001 and does not form any part of the upper surface 1195 of the insulation feature 119. This arrangement provides for a silicon nitride protection layer 2001 on the top of the refill dielectric material of the bottom layer 1601. As a result, the bottom layer 1601 is not damaged during later-performed interlayer dielectric (ILD) removal processes such as during formation of a metal contact to source/drain features.

Referring to FIG. 23, the silicon oxide layer 1601 is encapsulated by the silicon nitride layer 2001. Interlayer dielectric (ILD) material 231 is located over source/drain regions 232. During the further processing of method 10 or method 2400, a trench is etched through the ILD material 231 to the source/drain region 232, before a conductive material is deposited in the trench. In embodiments in which the ILD material 231 is silicon oxide, the etch used to remove the ILD material 231 would damage the silicon oxide layer 1601. However, the silicon nitride layer 2001 prevents such damage by covering the silicon oxide layer 1601 during ILD removal processes.

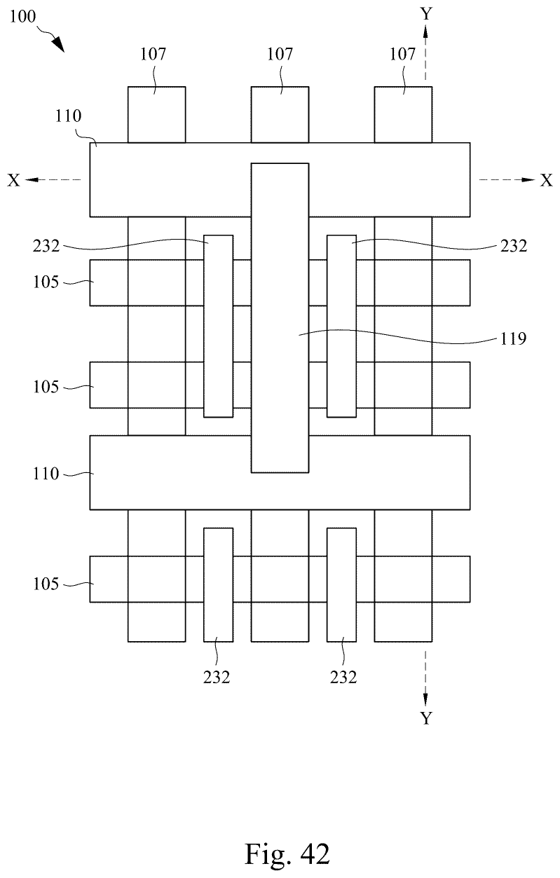

Referring now to FIGS. 42-46, another embodiment of a device 100 with an insulation feature 119 is illustrated. FIG. 42 illustrates a top-down view of an intermediate structure in forming a device 100, such as a gate-all-around (GAA) semiconductor device, according to some embodiments. In FIG. 42, fins 105 extend in the X-direction and are spaced from one another in the Y-direction. In FIG. 42, device 100 includes a plurality of gates 107 over the fins 105. The gates 107 extend in the Y-direction and are spaced from one another in the X-direction. Device 100 further includes source/drain regions 232.

FIG. 42 further illustrates a plurality of dielectric structures 110 separating the three gates 107 and an insulation feature 119 dividing two of the fins 105 in two and intersecting the dielectric structures 110. In the embodiment of FIG. 42, the dielectric structures 110 are formed as dummy fins. As shown, dummy fins 110 extend in the X-direction and are spaced from one another and from fins 105 in the Y-direction.

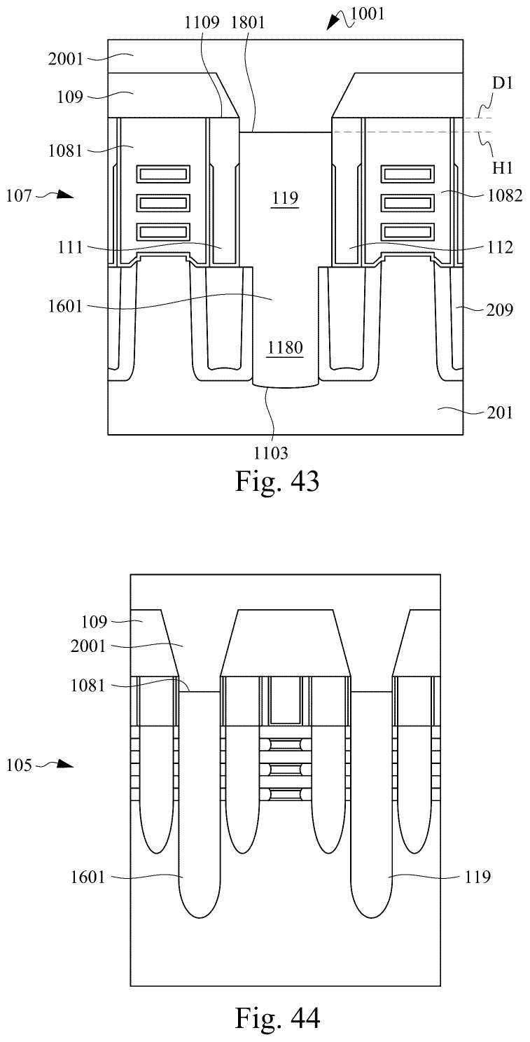

Referring to FIGS. 43 and 44, the structure of the device 100 is described further in accordance with a CMODE process for forming the insulation feature 119. FIG. 43 is a Y-cut cross-sectional view taken along a gate 107 and FIG. 44 is an X-cut cross-sectional view taken along a fin 105.

As shown, the dielectric structures 110, including a first dielectric structure 111 and a second dielectric structure 112, are dummy fins. The metal gate 107, including first metal gate segment 1081 and second metal gate segment 1082 are formed between dummy fins 111 and may abut dummy fins 111. Similar to the processing described above in FIGS. 10-15, after formation of the metal gates 107, a dielectric layer 109 is formed over the device 100, and an opening 1001 is formed in the dielectric layer 109. Then, the metal gate segment lying under the opening is removed, and the nanosheets and fin underlying the removed metal segment are then removed to form an opening 1103. Then, the first insulating material 1601 and second insulating material 2001 are formed, as described in relation to FIGS. 16-21.

In the embodiment of FIGS. 42-44, the interface 1801 of the first insulation layer 1601 and the second insulation layer 2001 is at a height H1 over substrate 201 that is lower than a dummy fin plane D1 defined by upper surfaces 1109 of the dummy fins 111 and 112.

The embodiment of FIGS. 43 and 44 forms the metal gate 107 before the insulation feature 119, such as in a CMODE process. It is noted that the structure of FIGS. 43 and 44 may be planarized, as described in relation to FIGS. 22 and 23 above.

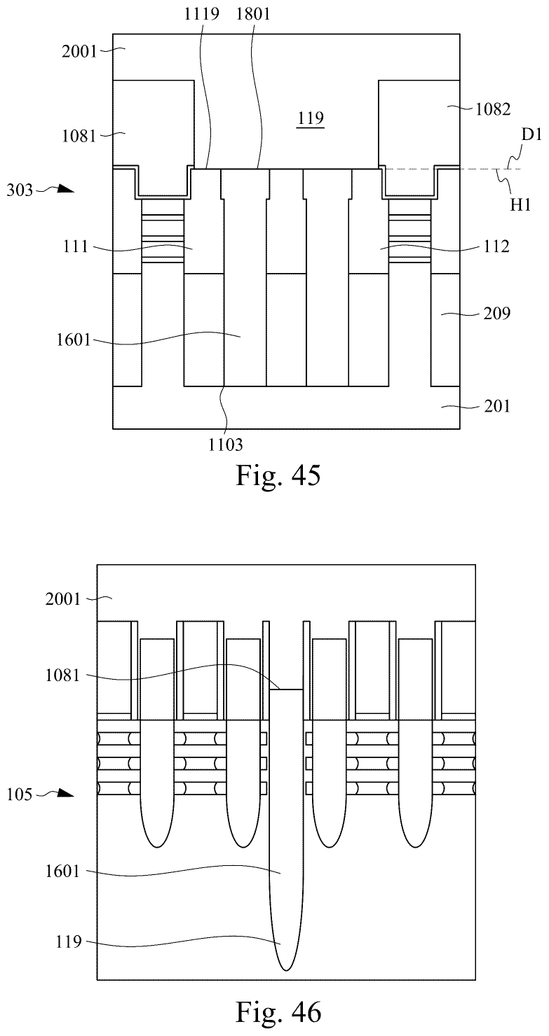

Referring to FIGS. 45 and 46, an embodiment of the device 100 of FIG. 42 is shown according to a CPODE process which forms the insulation feature 119 before the replacement metal gate process. FIG. 45 is a Y-cut cross-sectional view taken along a gate 107 and FIG. 46 is an X-cut cross-sectional view taken along a fin 105.

As shown, the dielectric structures 110, including a first dielectric structure 111 and a second dielectric structure 112, are dummy fins. The dummy gate 303, including first gate segment 1081 and second gate segment 1082 are formed over and between dummy fins 111 and may abut dummy fins 111. Similar to the processing described above in FIGS. 24-40, a gate segment located between gate segments 1081 and 1082 is removed, and the nanosheets and fins underlying the removed metal segment are then removed to form an opening 1103. Then, the first insulating material 1601 and second insulating material 2001 are formed.

In the embodiment of FIGS. 42 and 45-46, the interface 1801 of the first insulation layer 1601 and the second insulation layer 2001 is at a height H1 that is no higher than a dummy plane D1 defined by upper surfaces 1119 of the dummy fins 111 and 112.

It is noted that the structure of FIGS. 45 and 46 may be planarized, as described in relation to FIGS. 39 and 40 above.

In the embodiments of FIGS. 42-46, oxidation of the metal gate 107 is avoided by ensuring that the first insulating layer 1601 of silicon oxide does not exceed the upper surfaces 1119 of the dummy fins 111 and 112.

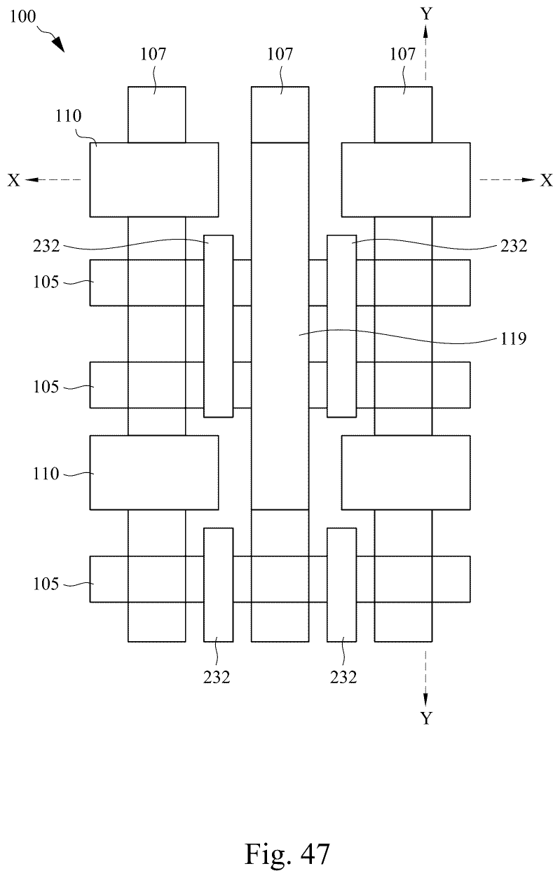

Referring now to FIGS. 47-51, another embodiment of a device 100 with an insulation feature 119 is illustrated. FIG. 47 illustrates a top-down view of an intermediate structure in forming a device 100, such as a gate-all-around (GAA) semiconductor device, according to some embodiments. In FIG. 47, fins 105 extend in the X-direction and are spaced from one another in the Y-direction. In FIG. 47, device 100 includes a plurality of gates 107 over the fins 105. The gates 107 extend in the Y-direction and are spaced from one another in the X-direction. Device 100 further includes source/drain regions 232.

FIG. 47 further illustrates a plurality of dielectric structures 110 separating two gates 107 into gate segments and an insulation feature 119 replacing a portion of a gate and dividing two of the fins 105 in two. In FIG. 47, the insulation feature 119 does not contact the dielectric structures 110.

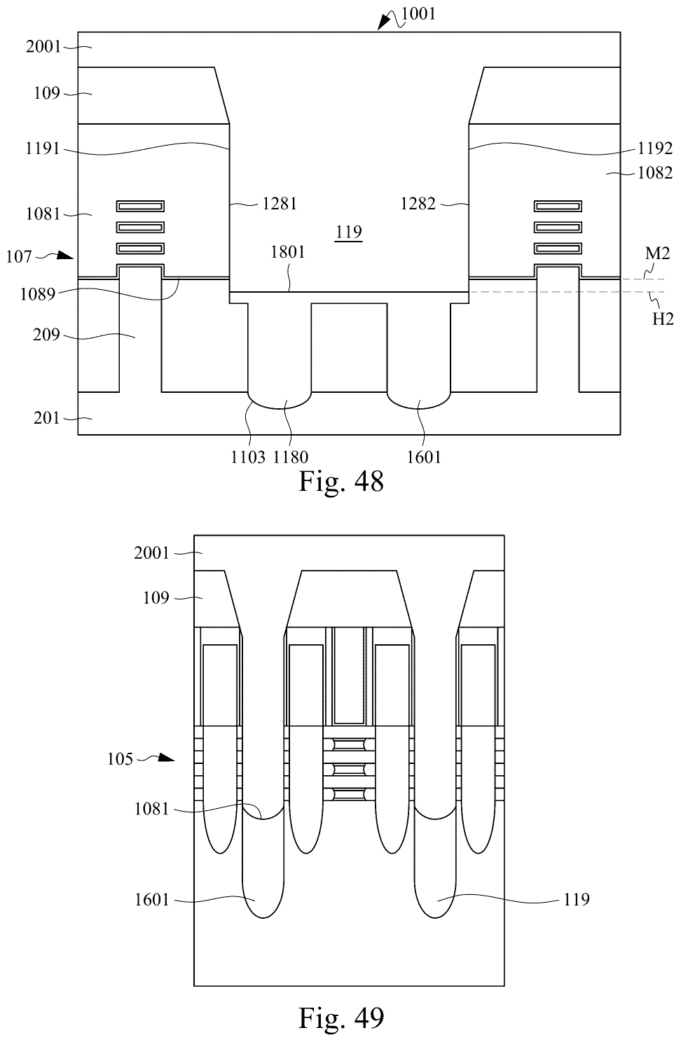

Referring to FIGS. 48 and 49, the structure of the device 100 is described further in accordance with a CMODE process for forming the insulation feature 119. FIG. 48 is a Y-cut cross-sectional view taken along a gate 107 and FIG. 49 is an X-cut cross-sectional view taken along a fin 105.

The structure of FIGS. 48 and 49 may formed by processing similar to method 10, but without the formation of dielectric structures 110. As a result, the metal gate segments 1081 and 1082 of the metal gate 107 are in direct contact with the insulation feature 119. Specifically, the insulation feature 119 extends laterally from a first sidewall 1191 abutting the first gate segment 1081 to a second sidewall 1192 abutting the second gate segment 1082.

Similar to the processing described above in FIGS. 10-15, after formation of the metal gates 107, a dielectric layer 109 is formed over the device 100, and an opening 1001 is formed in the dielectric layer 109. Then, the metal gate segment lying under the opening is removed, and the nanosheets and fin underlying the removed metal segment are then removed to form an opening 1103. Then, the first insulating material 1601 and second insulating material 2001 are formed, as described in relation to FIGS. 16-21.

In the embodiment of FIGS. 47-49, the interface 1801 of the first insulation layer 1601 and the second insulation layer 2001 is at a maximum height H2 that is lower than a metal gate plane M2 defined by lowest surfaces 1089 of gate segments 1081 and 1082.

It is noted that the structure of FIGS. 48 and 49 may be planarized, as described in relation to FIGS. 22 and 23 above.

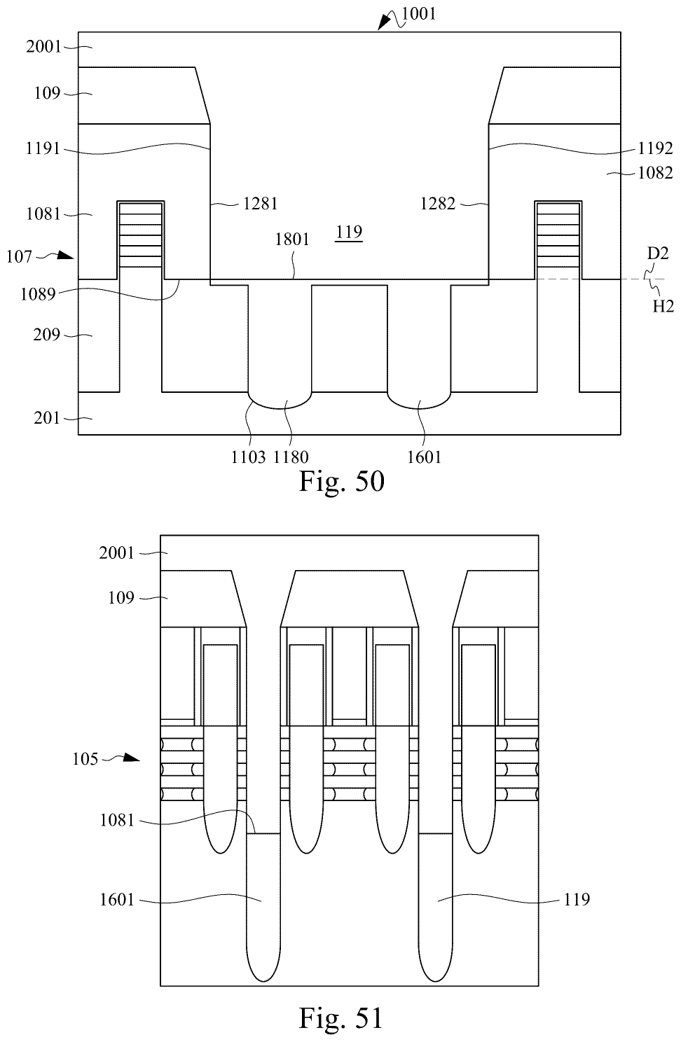

Referring to FIGS. 50 and 51, an embodiment of the device 100 of FIG. 47 is shown according to a CPODE process which forms the insulation feature 119 before the replacement metal gate process. FIG. 50 is a Y-cut cross-sectional view taken along a gate 107 and FIG. 50 is an X-cut cross-sectional view taken along a fin 105.

The structure of FIGS. 50 and 51 may formed by processing similar to method 2400, but without the formation of dielectric structures 110. As a result, the metal gate segments 1081 and 1082 of the metal gate 107 are in direct contact with the insulation feature 119. Specifically, the insulation feature 119 extends laterally from a first sidewall 1191 abutting the first gate segment 1081 to a second sidewall 1192 abutting the second gate segment 1082.

After formation of the dummy gates 303, a dielectric layer 109 is formed over the device 100, and an opening 1001 is formed in the dielectric layer 109. Then, the dummy gate segment lying under the opening is removed, and the nanosheets and fin underlying the removed dummy gate segment are then removed to form an opening 1103. Then, the first insulating material 1601 and second insulating material 2001 are formed, as described in relation to FIGS. 25-32.

In the embodiment of FIGS. 47 and 50-51, the interface 1801 of the first insulation layer 1601 and the second insulation layer 2001 is at a maximum height H2 that is lower than a dummy gate plane D2 defined by lowest surfaces 1089 of gate segments 1081 and 1082.

It is noted that the structure of FIGS. 50 and 51 may be planarized, as described in relation to FIGS. 39 and 40 above.

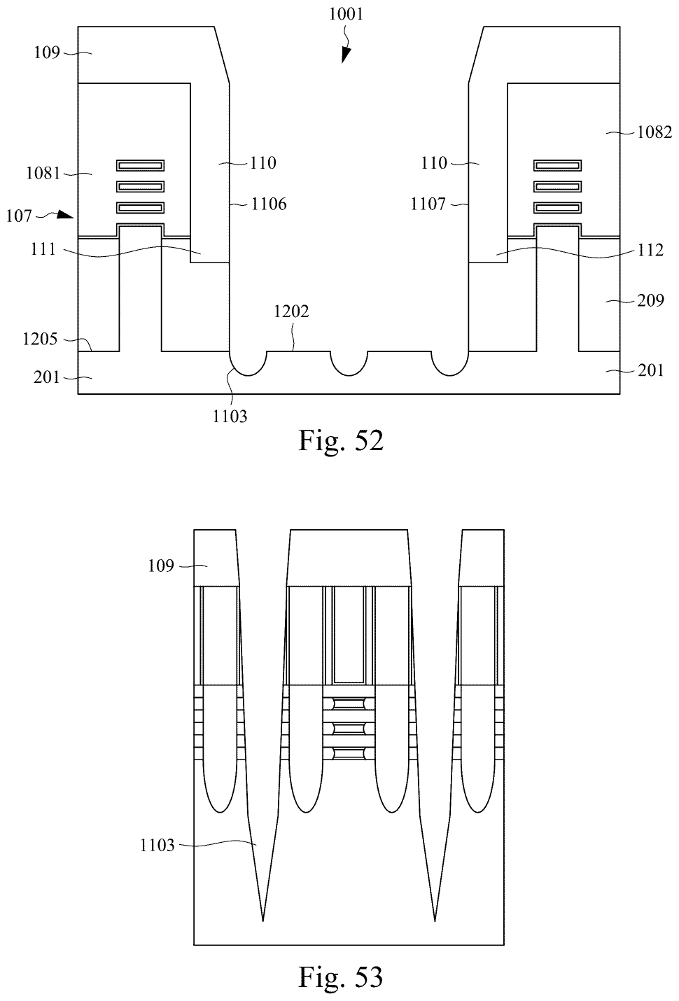

Another embodiment is described in relation to FIGS. 52-59, in which a CMODE process is performed, similar to method 10 and FIGS. 1-23. In the embodiment of FIGS. 52-59, the process is performed with a low selective etch when forming the opening 1103. FIG. 52 is a Y-cut cross-sectional view taken along a gate 107, similar to FIG. 10, and FIG. 53 is an X-cut cross-sectional view taken along a fin 105, similar to FIG. 11.

In FIGS. 52 and 53, method 10 may continue from operation S18 of method 10, with performing a low selectivity etch and performing operation S19 and operation S20 together to remove the metal gate segment 1080, including the metal gate material 107 and high k gate dielectric 703, nanostructures 701, and selected fins 105. Further, the uncovered portion of STI region 209 are also recessed to the substrate 201. As a result, an upper surface 1205 of the substrate 201 is recessed to a recessed surface 1202 as shown. The opening 1103 has sidewalls 1106 and 1107 defined by the dielectric structures 110 and STI regions 209. In FIG. 53, it may be seen that the opening 1103 is formed with a deep V-shape in such embodiments.

In certain embodiments, the etch process is a plasma etch.

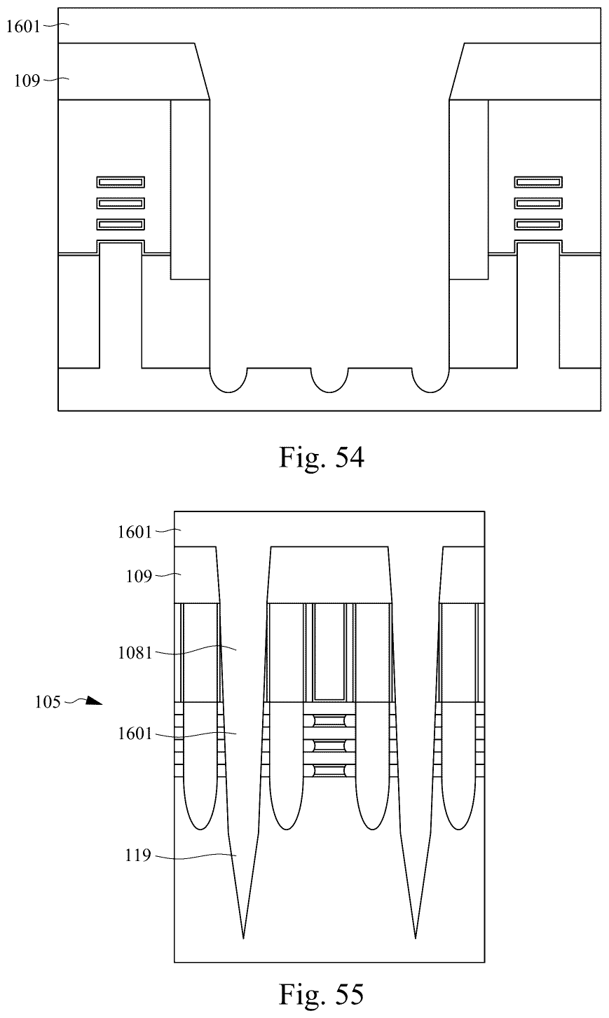

Cross-referencing FIG. 1 and FIGS. 54 and 55, method 10 may continue, at operation S21, with forming a first insulating dielectric material 1601 in the opening 1103. FIG. 54 is a Y-cut cross-sectional view taken along a gate 107, similar to FIG. 10, and FIG. 55 is an X-cut cross-sectional view taken along a fin 105, similar to FIG. 11.

As shown in FIGS. 54 and 55, the first insulating dielectric material 1601 may completely fill the openings 1103.

In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is low-k silicon oxide.

In certain embodiments, the first insulating dielectric material 1601 may be deposited with a refill process. In one example, the dielectric structure 1601 may be deposited by chemical vapor deposition (CVD), atomic layer deposition (ALD), spin-on coating, or other suitable techniques. As shown, the first insulating dielectric material 1601 may be first formed as a blanket layer covering the surface of the dielectric material 109.

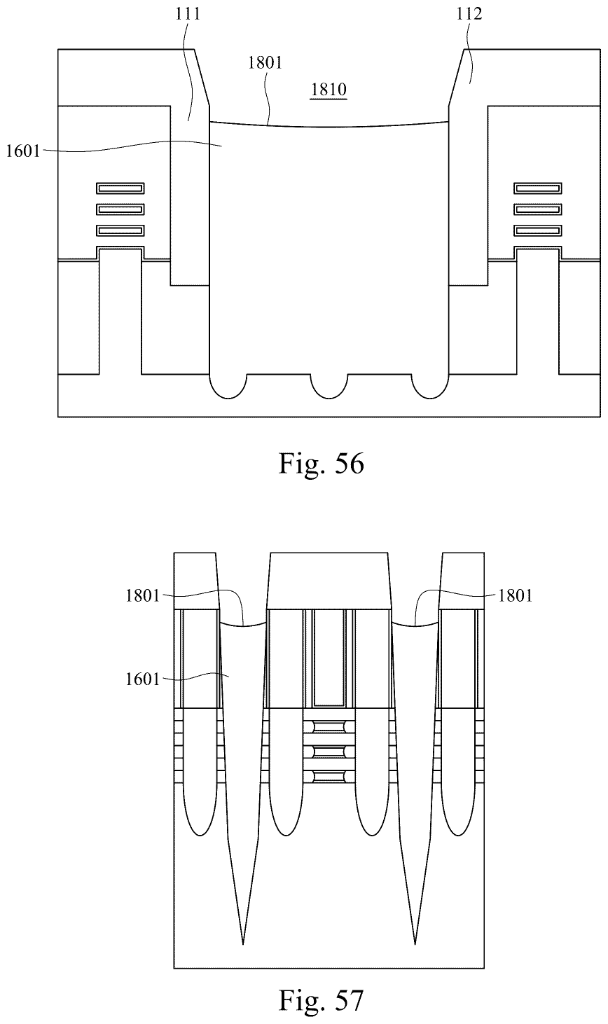

Cross-referencing FIG. 1 and FIGS. 56 and 57, method 10 may continue, at operation S22, with recessing the first insulating dielectric material 1601 to form a recess or opening 1810. FIG. 56 is a Y-cut cross-sectional view taken along a gate 107, similar to FIG. 10, and FIG. 57 is an X-cut cross-sectional view taken along a fin 105, similar to FIG. 11.

As shown in FIGS. 56 and 57, the first insulating dielectric material 1601 is recessed to a recessed surface 1801. The recessed surface 1801 extends laterally between dielectric pillars 110. Specifically, the recessed surface 1801 contacts a first dielectric pillar 111 and an adjacent second dielectric pillar 112.

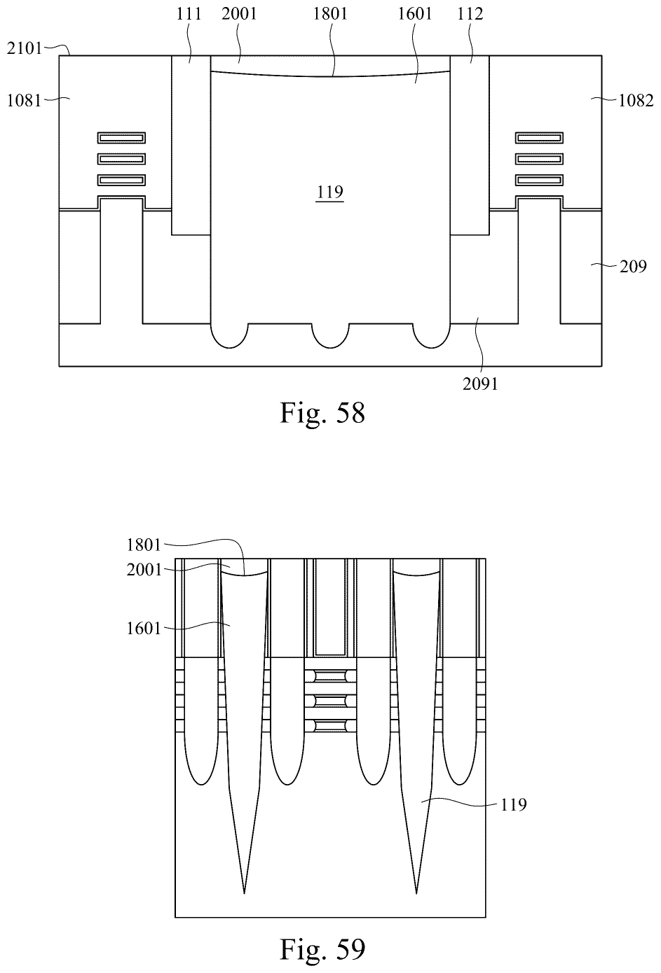

Cross-referencing FIG. 1 and FIGS. 58 and 59, method 10 may continue, at operation S23, with depositing a second insulating dielectric material 2001 in the opening 1810 over the first insulating dielectric material 1601. FIG. 58 is a Y-cut cross-sectional view taken along a gate 107, similar to FIG. 10, and FIG. 59 is an X-cut cross-sectional view taken along a fin 105, similar to FIG. 11.

As shown in FIGS. 58 and 59, the second insulating dielectric material 2001 may completely fill the openings 1810.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. The second insulating dielectric material 2001 may be first formed as a blanket layer covering the surface of the dielectric material 109.

Method 10 may continue, at operation S24, with planarizing the structure of device 100. As shown, the planarization process may remove all of the overburden portion of the dielectric material 109 and all of the overburden portion of the second insulating dielectric material 2001 and form the structure of device 100 with an upper surface 2101 formed by the first metal gate segment 1081, dielectric pillar 111, second insulating dielectric material 2001, dielectric pillar 112 and second metal gate segment 1082.

Operation S24 may be considered to complete the CMODE process by forming the insulation feature 119 in the form of a CMODE structure, include bottom layer or first insulating dielectric material 1601 and top layer or second insulating dielectric material 2001. As shown, each of the first insulating dielectric material 1601 and top layer or second insulating dielectric material 2001 contacts the first dielectric pillar 111 and the second dielectric pillar 112 such that the first insulating dielectric material 1601 is completely covered by, and encapsulated by, the second insulating dielectric material 2001.

As shown in FIG. 1, method 10 may continue, at operation S25, with further processing for completing the device 100. For example, the further processing may include forming interlayer dielectric and metallization layers, forming source/drain contacts to the source/drain regions, and forming source/drain vias and gate vias, in accordance with some embodiments.

Various embodiments are described herein in which latch-up and pick-up isolation issues are avoided by methods using CPODE or CMODE processes. Thus, transistors near the insulation features do not exhibit grounding issues.

In certain embodiments, devices herein exhibit low parasitic capacitance. Further, impact to well potential is minimized by adopting vertical stacking of insulators by optimizing the depth of the insulation feature. Further, the vertical stacking technique utilizes a silicon nitride protection layer on the top of silicon oxide refill dielectrics, enabling the prevention of damage to the oxide during later ILD removal processes.

In certain embodiments, such as in extreme scaling cases (no cut-poly or cut-metal dielectric structures in the line end of CPODE/CMODE), the maximum height of the refill silicon oxide should not contact the gate metal to have minimum impact on the gate composition. Likewise, for dummy fin approaches, the refill silicon oxide should not exceed the top of dummy fins to avoid oxidizing of the metal gate.

In an embodiment, a semiconductor device 100 is provided and includes a first fin structure 1051 located over a substrate 201; a first gate segment 1081 located over the first fin structure 1051; a second fin structure 1052 located over the substrate 201; a second gate segment 1082 located over the second fin structure 1052; and an insulation feature 119 located between the first fin structure 1051 and the second fin structure 1052 and located between the first gate segment 1081 and the second gate segment 1082, the insulation feature 119 extends laterally from a first sidewall 1191 nearest the first gate segment 1081 to a second sidewall 1192 nearest the second gate segment 1082; the insulation feature 119 includes a bottom layer 1601 and a top layer 2001 located over the bottom layer 1601; and the top layer 2001 forms an uppermost surface 1195 of the insulation feature 119.

In certain embodiments, the semiconductor device 100 further includes a shallow trench isolation (STI) region 209 overlying an upper surface 1205 of the substrate 201 and laterally adjacent to base portions 106 of the first fin structure 1051 and the second fin structure 1052, the insulation feature 119 includes a projection 1180 extending through the STI region 209 to a lowest surface 1185, and the lowest surface 1185 is within 5 nm of the upper surface 1205 of the substrate.

In certain embodiments of the semiconductor device 100, the projection 1180 extends through the STI region is formed by the bottom layer 1601.

In certain embodiments, the semiconductor device 100 further includes a shallow trench isolation (STI) region 209 laterally adjacent to base portions 106 of the first fin structure 1051 and the second fin structure 1052; a first dielectric pillar 111 extending vertically from the uppermost surface 1195 of the insulation feature 119 to the STI region 209; and a second dielectric pillar 112 extending vertically from the uppermost surface 1195 of the insulation feature 119 to the STI region 209; the first sidewall 1191 of the insulation feature 119 contacts the first dielectric pillar 111 and the second sidewall 1192 of the insulation feature 119 contacts the second dielectric pillar 112.

In certain embodiments of the semiconductor device 100, the first dielectric pillar 111 is a first dummy fin; the second dielectric pillar 112 is a second dummy fin; an uppermost surface 1195 of the insulation feature 119 contacts an uppermost surface 1115 of the first dummy fin 111 and an uppermost surface 1125 of the second dummy fin 112; and the uppermost surface 1195 of the insulation feature 119 is formed by the top layer 2001 such that the bottom layer 1601 is encapsulated by the top layer 2001, the first dummy fin 111 and the second dummy fin 112.

In certain embodiments of the semiconductor device 100, the first dielectric pillar 111 is a first cut gate dielectric; the second dielectric pillar 112 is a second cut gate dielectric; an uppermost surface 1195 of the insulation feature 119 contacts an uppermost surface 1115 of the first cut gate dielectric 111 and an uppermost surface 1125 of the second cut gate dielectric 112; and the uppermost surface 1195 of the insulation feature 119 is formed by the top layer 2001 such that the bottom layer 1601 is encapsulated by the top layer 2001, the first cut gate dielectric 111 and the second cut gate dielectric 112.

In certain embodiments of the semiconductor device 100, the first dielectric pillar 111 is a first cut gate dielectric; the second dielectric pillar 112 is a second cut gate dielectric; an interface 1801 is defined between the bottom layer 1601 and the top layer 2001; and the interface 1801 contacts the first cut gate dielectric 111 and the second cut gate dielectric 112.

In certain embodiments of the semiconductor device 100, the first dielectric pillar 111 is a first cut gate dielectric; the second dielectric pillar 112 is a second cut gate dielectric; an interface 1801 is defined between the bottom layer 1601 and the top layer 2001 at an interface height above the substrate; the interface 1801 contacts the first cut gate dielectric 111 and the second cut gate dielectric 112; an uppermost surface 1055 of the first fin structure and of the second fin structure define an uppermost fin plane F1; and the uppermost fin plane F1 is located between the interface height and the substrate 201.

In certain embodiments of the semiconductor device 100, the insulation feature 119 directly contacts the first gate segment 1081 and the second gate segment 1082.

In certain embodiments of the semiconductor device 100, the insulation feature 119 directly contacts the first gate segment 1081 and the second gate segment 1082; an interface 1801 is defined between the bottom layer 1601 and the top layer 2001 at an interface height above the substrate 201; a lowest surface of the first gate segment and a lowest surface of the second gate segment define a gate bottom plane; and the interface height is located between the gate bottom plane and the substrate.

In certain embodiments, the semiconductor device 100 further includes a shallow trench isolation (STI) region overlying an upper surface of the substrate and adjacent to base portions of the first fin structure and the second fin structure, wherein: an interface is defined between the bottom layer and the top layer; the interface contacts the STI region at the first sidewall of the insulation feature; and the interface contacts the STI region at the second sidewall of the insulation feature.

In another embodiment, a method is provided and includes forming fins over a substrate; forming a gate over the fins; removing a selected segment of the gate; removing at least one fin located under the selected segment to form a cavity formed with sidewalls; forming a first insulating dielectric in the cavity, the first insulating dielectric has an upper surface contacting the sidewalls of the cavity; and forming a second insulating dielectric in the cavity over the first insulating dielectric, wherein the first insulating dielectric and the second insulating dielectric are made of different materials.

In certain embodiments, the method further includes forming isolation regions between base portions of the fins; removing a first section of the gate to form a first trench extending to a first isolation region; removing a second section of the gate to form a second trench extending to a second isolation region, the at least one fin lies between the first trench and the second trench; and depositing a dielectric material in the first trench and second trench to form a first dielectric pillar and a second dielectric pillar, the selected segment of the gate lies between the first dielectric pillar and the second dielectric pillar.

In certain embodiments, the method further includes forming isolation regions between base portions of the fins, removing the at least one fin located under the selected segment forms the cavity with a bottom surface, and the bottom surface is less than 5 nm from a bottom surface of the isolation regions.

In certain embodiments, the method further includes forming a first dummy fin and a second dummy fin over the substrate, the at least one fin is located between the first dummy fin and the second dummy fin, and sidewalls of the cavity are formed by the first dummy fin and the second dummy fin.

In another embodiment, a method is provided and includes forming semiconductor structures; forming an isolation region between the semiconductor structures, the isolation region has a bottom surface; forming a first dielectric pillar and a second dielectric pillar in and over the isolation region; forming a gate over the semiconductor structures; removing a selected segment of the gate to form a cavity, the cavity extends to a bottom cavity surface located at or below the bottom surface of the isolation region, and the selected segment is located between the first dielectric pillar and the second dielectric pillar; and forming an insulation feature in the cavity, the insulation feature includes a top layer over a bottom layer, the top layer and bottom layer are formed from dissimilar materials, and an interface between the top layer and bottom layer contacts the first dielectric pillar and the second dielectric pillar.

In certain embodiments of the method, the gate is formed before forming the first dielectric pillar and the second dielectric pillar, and the method further includes: removing a first section of the gate to form a first trench extending to a first isolation region; and removing a second section of the gate to form a second trench extending to a second isolation region, forming the first dielectric pillar and the second dielectric pillar includes depositing a dielectric material in the first trench and second trench.

In certain embodiments of the method, the gate is formed after forming the first dielectric pillar and the second dielectric pillar, and forming the gate includes forming the gate over the semiconductor structures, over the first dielectric pillar, and over the second dielectric pillar.

In certain embodiments of the method, the gate is a metal gate.

In certain embodiments of the method, the gate is a dummy gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first fin structure located over a substrate;
a first gate segment located over the first fin structure;
a second fin structure located over the substrate;
a second gate segment located over the second fin structure; and
an insulation feature located between the first fin structure and the second fin structure and located between the first gate segment and the second gate segment, wherein the insulation feature extends laterally from a first sidewall nearest the first gate segment to a second sidewall nearest the second gate segment;
wherein the insulation feature comprises a bottom layer and a top layer located over the bottom layer; and
wherein the top layer forms an uppermost surface of the insulation feature.

2. The semiconductor device of claim 1, further comprising a shallow trench isolation (STI) region overlying an upper surface of the substrate and laterally adjacent to base portions of the first fin structure and the second fin structure, and wherein the insulation feature includes a projection extending through the STI region to a lowest surface.

3. The semiconductor device of claim 2, wherein the projection extending through the STI region is formed by the bottom layer.

4. The semiconductor device of claim 1, further comprising:
a shallow trench isolation (STI) region laterally adjacent to base portions of the first fin structure and the second fin structure;
a first dielectric pillar extending vertically from the uppermost surface of the insulation feature to the STI region; and
a second dielectric pillar extending vertically from the uppermost surface of the insulation feature to the STI region;
wherein the first sidewall of the insulation feature contacts the first dielectric pillar and the second sidewall of the insulation feature contacts the second dielectric pillar.

5. The semiconductor device of claim 4, wherein:
the first dielectric pillar is a first dummy fin;
the second dielectric pillar is a second dummy fin;
an uppermost surface of the insulation feature contacts an uppermost surface of the first dummy fin and an uppermost surface of the second dummy fin; and
the uppermost surface of the insulation feature is formed by the top layer such that the bottom layer is encapsulated by the top layer, the first dummy fin and the second dummy fin.

6. The semiconductor device of claim 4, wherein:
the first dielectric pillar is a first cut gate dielectric;
the second dielectric pillar is a second cut gate dielectric;
an uppermost surface of the insulation feature contacts an uppermost surface of the first cut gate dielectric and an uppermost surface of the second cut gate dielectric; and
the uppermost surface of the insulation feature is formed by the top layer such that the bottom layer is encapsulated by the top layer, the first cut gate dielectric and the second cut gate dielectric.

7. The semiconductor device of claim 4, wherein:
the first dielectric pillar is a first cut gate dielectric;
the second dielectric pillar is a second cut gate dielectric;
an interface is defined between the bottom layer and the top layer; and
the interface contacts the first cut gate dielectric and the second cut gate dielectric.

8. The semiconductor device of claim 4, wherein:
the first dielectric pillar is a first cut gate dielectric;
the second dielectric pillar is a second cut gate dielectric;
an interface is defined between the bottom layer and the top layer at an interface height above the substrate;
the interface contacts the first cut gate dielectric and the second cut gate dielectric;
an uppermost surface of the first fin structure and of the second fin structure define an uppermost fin plane; and
the uppermost fin plane is located between the interface height and the substrate.

9. The semiconductor device of claim 1, wherein the insulation feature directly contacts the first gate segment and the second gate segment.

10. The semiconductor device of claim 1, wherein:
the insulation feature directly contacts the first gate segment and the second gate segment;
an interface is defined between the bottom layer and the top layer at an interface height above the substrate;
a lowest surface of the first gate segment and a lowest surface of the second gate segment define a gate bottom plane; and
the interface height is located between the gate bottom plane and the substrate.

11. The semiconductor device of claim 1, further comprising a shallow trench isolation (STI) region overlying an upper surface of the substrate and adjacent to base portions of the first fin structure and the second fin structure, wherein:
an interface is defined between the bottom layer and the top layer;
the interface contacts the STI region at the first sidewall of the insulation feature; and
the interface contacts the STI region at the second sidewall of the insulation feature.

12. A method comprising:
forming fins over a substrate;
forming a gate over the fins;
removing a selected segment of the gate;
removing at least one fin located under the selected segment to form a cavity formed with sidewalls;
forming a first insulating dielectric in the cavity, wherein the first insulating dielectric has an upper surface contacting the sidewalls of the cavity; and
forming a second insulating dielectric in the cavity over the first insulating dielectric, wherein the first insulating dielectric and the second insulating dielectric are made of different materials.

13. The method of claim 12, further comprising:
forming isolation regions between base portions of the fins;
removing a first section of the gate to form a first trench extending to a first isolation region;
removing a second section of the gate to form a second trench extending to a second isolation region, wherein the at least one fin lies between the first trench and the second trench; and
depositing a dielectric material in the first trench and second trench to form a first dielectric pillar and a second dielectric pillar, wherein the selected segment of the gate lies between the first dielectric pillar and the second dielectric pillar.

14. The method of claim 12, further comprising forming isolation regions between base portions of the fins, wherein removing the at least one fin located under the selected segment forms the cavity with a bottom surface, and wherein the bottom surface is less than 5 nm from a bottom surface of the isolation regions.

15. The method of claim 12, further comprising forming a first dummy fin and a second dummy fin over the substrate, wherein the at least one fin is located between the first dummy fin and the second dummy fin, and wherein sidewalls of the cavity are formed by the first dummy fin and the second dummy fin.

16. A method comprising:
forming semiconductor structures;
forming an isolation region between the semiconductor structures, wherein the isolation region has a bottom surface;
forming a first dielectric pillar and a second dielectric pillar in and over the isolation region;
forming a gate over the semiconductor structures;
removing a selected segment of the gate to form a cavity, wherein the cavity extends to a bottom cavity surface located at or below the bottom surface of the isolation region, and wherein the selected segment is located between the first dielectric pillar and the second dielectric pillar; and
forming an insulation feature in the cavity, wherein the insulation feature includes a top layer over a bottom layer, wherein the top layer and bottom layer are formed from dissimilar materials, and wherein an interface between the top layer and bottom layer contacts the first dielectric pillar and the second dielectric pillar.

17. The method of claim 16, wherein the gate is formed before forming the first dielectric pillar and the second dielectric pillar, and wherein the method further comprises:
removing a first section of the gate to form a first trench extending to a first isolation region; and
removing a second section of the gate to form a second trench extending to a second isolation region, wherein forming the first dielectric pillar and the second dielectric pillar comprises depositing a dielectric material in the first trench and second trench.

18. The method of claim 16, wherein the gate is formed after forming the first dielectric pillar and the second dielectric pillar, and wherein forming the gate comprises forming the gate over the semiconductor structures, over the first dielectric pillar, and over the second dielectric pillar.

19. The method of claim 16, wherein the gate comprises a metal gate.

20. The method of claim 16, wherein the gate comprises a dummy gate.
